(19) United States
(12) Patent Application Publication
(10) Pub. No.: US 2025/0283979 A1
(43) Pub. Date: Sep. 11, 2025

(54) SURFACE-EMITTING LASER, LIGHT SOURCE DEVICE, AND RANGING DEVICE

(71) Applicant: SONY GROUP CORPORATION, TOKYO (JP)

(72) Inventors: TOMOMASA WATANABE, TOKYO (JP); MIKIHIRO YOKOZEKI, TOKYO (JP); HIROSHI NAKAJIMA, TOKYO (JP)

(21) Appl. No.: 18/839,663

(22) PCT Filed: Jan. 10, 2023
(86) PCT No.: PCT/JP2023/000292

§ 371 Date: May 14, 2025

(30) Foreign Application Priority Data
Feb. 25, 2022 (JP) 2022-028346

(51) Int. Cl. G01S 7/481; G01S 17/08

(52) U.S. Cl. CPC G01S 7/4814; G01S 17/08

(57) ABSTRACT

Provided is a surface-emitting laser having a light confinement structure, which can reduce manufacturing costs. The surface-emitting laser according to the present technique includes first and second reflectors, an active layer disposed between the first and second reflectors, and a semiconductor structure disposed between the active layer and the second reflector. An annular step part is provided on a surface of the semiconductor structure on a side where the second reflector is located. According to the present technique, the surface-emitting laser having the light confinement structure, which can reduce manufacturing costs, can be provided.

### TECHNICAL FIELD

The technique according to the present disclosure (hereinafter also called “the present technique”) relates to a surface-emitting laser, a light source device, and a ranging device.

### BACKGROUND ART

Conventionally, surface-emitting lasers having buried tunnel junctions (BTJs) have been known as light confinement structures (see PTL 1, for example).

### CITATION LIST

### Patent Literature

### PTL 1

WO 2004/049461

### SUMMARY

### Technical Problem

However, with such conventional surface-emitting lasers, there is room for improvement in terms of reducing manufacturing costs.

Accordingly, a main object of the present technique is to provide a surface-emitting laser having a light confinement structure, which can reduce manufacturing costs.

### Solution to Problem

The present technique provides a surface-emitting laser including:
first and second reflectors;
an active layer disposed between the first and second reflectors; and
a semiconductor structure disposed between the active layer and the second reflector,
wherein an annular step part is provided on a surface of the semiconductor structure on a side where the second reflector is located.

The semiconductor structure may be provided with a current confinement region having at least one annular light-emitting region setting part that sets a light-emitting region of the active layer, and in plan view, the annular step part may surround a center of the light-emitting region.

In plan view, the annular step part may extend along an inner peripheral edge of the light-emitting region setting part.

In plan view, the annular step part may extend along an inner side of the inner peripheral edge.

In plan view, the annular step part may extend along the inner peripheral edge while overlapping with the inner peripheral edge.

The semiconductor structure may include a cladding layer, one surface of which is the surface.

A base surface of the annular step part may be located within the cladding layer. A surface layer including the one surface of the cladding layer may be constituted by a material lattice-matched to InP and/or InP.

The material may be a mixed crystal.

An annular low refractive index layer having a lower refractive index than the cladding layer may be provided in contact with the annular step part.

The low refractive index layer may be constituted by a dielectric.

The second reflector may be a dielectric multilayer reflector, and the low refractive index layer may be one of a pair in the dielectric multilayer reflector.

A vertical cross-section of the annular step part may have a tapered shape.

The low refractive index layer may be constituted by SiO₂ or Al₂O₃.

The semiconductor structure may include another cladding layer disposed between the cladding layer and the active layer, and a tunnel junction layer disposed between the cladding layer and the other cladding layer.

The surface-emitting laser may further include a cladding layer that is disposed between the first reflector and the active layer and is formed from a material system of the same type as the semiconductor structure. A structure including the first reflector and the cladding layer may be bonded together, and the structure including the first reflector and the semiconductor structure may be formed from different material systems.

The surface-emitting laser may further include a cladding layer disposed between the first reflector and the active layer, and the active layer, the semiconductor structure, and the cladding layer may be constituted by materials lattice-matched to GaAs.

The current confinement region may include a plurality of the light-emitting region setting parts.

The present technique also provides a light source device including:
the surface-emitting laser; and
a circuit board bonded to a surface of the surface-emitting laser on the first reflector side thereof.

The present technique also provides a ranging device including:
the light source device; and
a light-receiving element mounted on the circuit board of the light source device.

### BRIEF DESCRIPTION OF DRAWINGS

FIG. 1 is a cross-sectional view of a surface-emitting laser according to Example 1 of a first embodiment of the present technique.

FIG. 2 is a plan view of the surface-emitting laser illustrated in FIG. 1.

FIG. 3 is a flowchart illustrating an example of a method for manufacturing the surface-emitting laser illustrated in FIG. 1.

FIG. 4A and FIG. 4B are cross-sectional views illustrating respective steps in the example of the method for manufacturing the surface-emitting laser illustrated in FIG. 1.

FIG. 5A and FIG. 5B are cross-sectional views illustrating respective steps in the example of the method for manufacturing the surface-emitting laser illustrated in FIG. 1.

FIG. 6A and FIG. 6B are cross-sectional views illustrating respective steps in the example of the method for manufacturing the surface-emitting laser illustrated in FIG. 1.

FIG. 7A and FIG. 7B are cross-sectional views illustrating respective steps in the example of the method for manufacturing the surface-emitting laser illustrated in FIG. 1.

FIG. 8A and FIG. 8B are cross-sectional views illustrating respective steps in the example of the method for manufacturing the surface-emitting laser illustrated in FIG. 1.

FIG. 9A and FIG. 9B are cross-sectional views illustrating respective steps in the example of the method for manufacturing the surface-emitting laser illustrated in FIG. 1.

FIG. 10 is a cross-sectional view of a surface-emitting laser according to Example 2 of the first embodiment of the present technique.

FIG. 11 is a cross-sectional view of a surface-emitting laser according to Example 3 of the first embodiment of the present technique.

FIG. 12 is a flowchart illustrating an example of a method for manufacturing the surface-emitting laser illustrated in FIG. 11.

FIG. 13A and FIG. 13B are cross-sectional views illustrating respective steps in the example of the method for manufacturing the surface-emitting laser illustrated in FIG. 11.

FIG. 14A and FIG. 14B are cross-sectional views illustrating respective steps in the example of the method for manufacturing the surface-emitting laser illustrated in FIG. 11.

FIG. 15 is a cross-sectional view illustrating respective steps in the method for manufacturing the surface-emitting laser illustrated in FIG. 11.

FIG. 16 is a cross-sectional view of a surface-emitting laser according to Example 4 of the first embodiment of the present technique.

FIG. 17 is a flowchart illustrating an example of a method for manufacturing the surface-emitting laser illustrated in FIG. 16.

FIG. 18A and FIG. 18B are cross-sectional views illustrating respective steps in the example of the method for manufacturing the surface-emitting laser illustrated in FIG. 16.

FIG. 19 is a cross-sectional view of a surface-emitting laser according to Example 5 of the first embodiment of the present technique.

FIG. 20 is a flowchart illustrating an example of a method for manufacturing the surface-emitting laser illustrated in FIG. 19.

FIG. 21A and FIG. 21B are cross-sectional views illustrating respective steps in the example of the method for manufacturing the surface-emitting laser illustrated in FIG. 19.

FIG. 22A and FIG. 22B are cross-sectional views illustrating respective steps in the example of the method for manufacturing the surface-emitting laser illustrated in FIG. 19.

FIG. 23A and FIG. 23B are cross-sectional views illustrating respective steps in the example of the method for manufacturing the surface-emitting laser illustrated in FIG. 19.

FIG. 24A and FIG. 24B are cross-sectional views illustrating respective steps in the example of the method for manufacturing the surface-emitting laser illustrated in FIG. 19.

FIG. 25A and FIG. 25B are cross-sectional views illustrating respective steps in the example of the method for manufacturing the surface-emitting laser illustrated in FIG. 19.

FIG. 26A and FIG. 26B are cross-sectional views illustrating respective steps in the example of the method for manufacturing the surface-emitting laser illustrated in FIG. 19.

FIG. 27 is a cross-sectional view of a surface-emitting laser according to Example 6 of the first embodiment of the present technique.

FIG. 28 is a flowchart illustrating an example of a method for manufacturing the surface-emitting laser illustrated in FIG. 27.

FIG. 29A and FIG. 29B are cross-sectional views illustrating respective steps in the example of the method for manufacturing the surface-emitting laser illustrated in FIG. 27.

FIG. 30 is a cross-sectional view illustrating a step in the example of the method for manufacturing the surface-emitting laser illustrated in FIG. 27.

FIG. 31 is a cross-sectional view of a surface-emitting laser according to Example 7 of the first embodiment of the present technique.

FIG. 32 is a cross-sectional view of a surface-emitting laser according to Example 8 of the first embodiment of the present technique.

FIG. 33 is a cross-sectional view of a surface-emitting laser according to Example 9 of the first embodiment of the present technique.

FIG. 34 is a cross-sectional view of a surface-emitting laser according to Example 10 of the first embodiment of the present technique.

FIG. 35 is a cross-sectional view of a surface-emitting laser according to Example 11 of the first embodiment of the present technique.

FIG. 36 is a cross-sectional view of a surface-emitting laser according to Example 12 of the first embodiment of the present technique.

FIG. 37 is a plan view of a surface-emitting laser according to Example 12 of the first embodiment of the present technique.

FIG. 38 is a cross-sectional view of a ranging device including the surface-emitting laser according to Example 12 of the first embodiment of the present technique.

FIG. 39 is a cross-sectional view of a surface-emitting laser according to a variation on Example 1 of the first embodiment of the present technique.

FIG. 40 is a cross-sectional view of a surface-emitting laser according to a variation on Example 4 of the first embodiment of the present technique.

FIG. 41 is a cross-sectional view of a surface-emitting laser according to a variation on Example 5 of the first embodiment of the present technique.

FIG. 42 is a cross-sectional view of a surface-emitting laser according to a variation on Example 12 of the first embodiment of the present technique.

FIG. 43 is a cross-sectional view of a surface-emitting laser according to Example 1 of a second embodiment of the present technique.

FIG. 44 is a cross-sectional view of a surface-emitting laser according to Example 2 of the second embodiment of the present technique.

FIG. 45 is a cross-sectional view of a surface-emitting laser according to Example 3 of the second embodiment of the present technique.

FIG. 46 is a cross-sectional view of a surface-emitting laser according to Example 4 of the second embodiment of the present technique.

FIG. 47 is a cross-sectional view of an example in which the surface-emitting laser according to the present technique is applied in a distance measurement device.

FIG. 48 is a block diagram illustrating an example of the overall configuration of a vehicle control system.

FIG. 49 is an explanatory diagram illustrating an example of an installation position of a distance measurement device.

### DESCRIPTION OF EMBODIMENTS

Hereinafter, preferred embodiments of the present technique will be described in detail with reference to the accompanying drawings. In the present specification and the drawings, components having substantially the same functional configuration will be denoted by the same reference signs, and repeated descriptions thereof will be omitted. The following embodiments describe representative embodiments of the present technique, and the scope of the present technique should not be narrowly interpreted on the basis thereof. Although the present specification will describe a surface-emitting laser, a light source device, and a ranging device according to the present technique as having a plurality of effects, it is sufficient for the surface-emitting laser, the light source device, and the ranging device according to the present technique to have at least one effect. The advantageous effects described in the present specification are merely exemplary and are not limited, and other advantageous effects may be obtained.

The descriptions will be given in the following order.
0. Introduction
1. Surface-Emitting Laser According to Example 1 of First Embodiment of Present Technique
2. Surface-Emitting Laser According to Example 2 of First Embodiment of Present Technique
3. Surface-Emitting Laser According to Example 3 of First Embodiment of Present Technique
4. Surface-Emitting Laser According to Example 4 of First Embodiment of Present Technique
5. Surface-Emitting Laser According to Example 5 of First Embodiment of Present Technique
6. Surface-Emitting Laser According to Example 6 of First Embodiment of Present Technique
7. Surface-Emitting Laser According to Example 7 of First Embodiment of Present Technique
8. Surface-Emitting Laser According to Example 8 of First Embodiment of Present Technique
9. Surface-Emitting Laser According to Example 9 of First Embodiment of Present Technique
10. Surface-Emitting Laser According to Example 10 of First Embodiment of Present Technique
11. Surface-Emitting Laser According to Example 11 of First Embodiment of Present Technique
12. Surface-Emitting Laser According to Example 12 of First Embodiment of Present Technique
13. Light Source Device Including Surface-Emitting Laser According to Example 12 of First Embodiment of Present Technique, and Ranging Device Including Light Source Device
14. Surface-Emitting Laser According to Variation on Example 1 of First Embodiment of Present Technique
15. Surface-Emitting Laser According to Variation on Example 4 of First Embodiment of Present Technique
16. Surface-Emitting Laser According to Variation on Example 5 of First Embodiment of Present Technique
17. Surface-Emitting Laser According to Variation on Example 12 of First Embodiment of Present Technique
18. Surface-Emitting Laser According to Example 1 of Second Embodiment of Present Technique
19. Surface-Emitting Laser According to Example 2 of Second Embodiment of Present Technique
20. Surface-Emitting Laser According to Example 3 of Second Embodiment of Present Technique
21. Surface-Emitting Laser According to Example 4 of Second Embodiment of Present Technique
22. Other Variations on Present Technique
23. Example of Application to Electronic Device
24. Example of Applying Surface-Emitting Laser to Distance Measurement Device
25. Example of Installing Distance Measurement Device on Moving Body

### 0. Introduction

Generally, a BTJ structure having a tunnel junction layer buried through epitaxial regrowth is used for light confinement in InP-based Vertical Cavity Surface Emitting Lasers (VCSELs). This structure provides a light confinement effect due to refractive index differences in the material in the lateral direction, but also has a problem in which manufacturing costs rise resulting from an increase in processing and lower yields due to the epitaxial regrowth.

Accordingly, after diligent investigations by the inventors, a main object is to provide a surface-emitting laser having a light confinement structure, which can reduce manufacturing costs.

Several examples of surface-emitting lasers according to a first embodiment of the present technique will be described in detail hereinafter.

### 1. Surface-Emitting Laser According to Example 1 of First Embodiment of Present Technique

A surface-emitting laser 10-1 according to Example 1 of the first embodiment of the present technique will be described hereinafter.

### Configuration of Surface-Emitting Laser

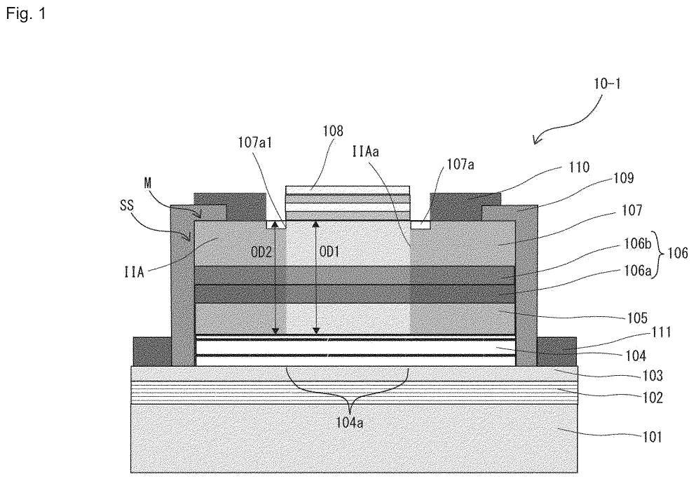

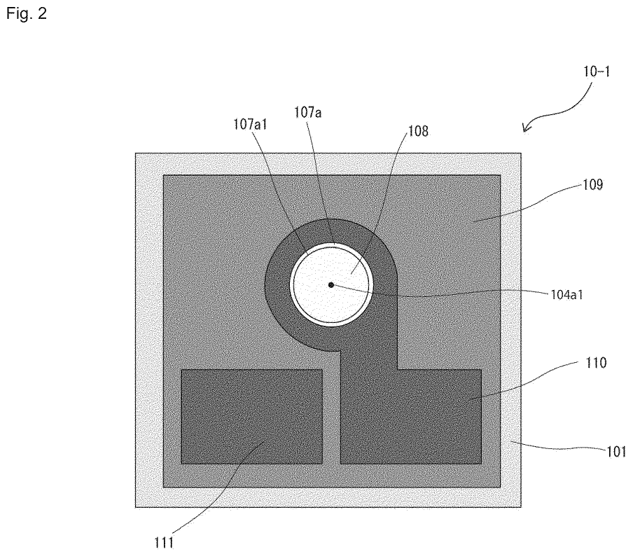

FIG. 1 is a cross-sectional view of the surface-emitting laser 10-1 according to Example 1 of the first embodiment of the present technique. FIG. 2 is a plan view of the surface-emitting laser 10-1. For the sake of convenience, the following will describe the upper part and the lower part in the cross-sectional view in FIG. 1 and the like as the “top” and the “bottom”, respectively.

The surface-emitting laser 10-1 is a Vertical Cavity Surface Emitting Laser (VCSEL). The surface-emitting laser 10-1 is, for example, an InP-based VCSEL having an oscillation wavelength A of 900 nm or more, for example. The surface-emitting laser 10-1 is driven by a laser driver, for example.

For example, as illustrated in FIG. 1, the surface-emitting laser 10-1 includes first and second reflectors 102 and 108, an active layer 104 disposed between the first and second reflectors 102 and 108, and a semiconductor structure SS disposed between the active layer 104 and the second reflector 108. The surface-emitting laser 10-1 further includes, for example, a substrate 101 disposed on the side of the first reflector 102 opposite from the side on which the active layer 104 is located, and a cladding layer 103 disposed between the first reflector 102 and the active layer 104.

The semiconductor structure SS includes a cladding layer 107 which has one surface on the second reflector 108 side, a cladding layer 105 (another cladding layer) disposed between the cladding layer 107 and the active layer 104, and a tunnel junction layer 106 disposed between the two cladding layers 105 and 107.

For example, a mesa M is configured including the semiconductor structure SS and the active layer 104. At least a side surface of the mesa M is covered by an insulating film 109. The second reflector 108 is provided on a central part of a top part of the mesa M (e.g., the cladding layer 107). An annular (e.g., ring-shaped) anode electrode 110 is provided on a peripheral part of the top part of the mesa M so as to surround the second reflector 108. A cathode electrode 111 is disposed on a region (e.g., of the cladding layer 103) in the periphery of a bottom part of the mesa M, the side surface of which is covered by the insulating film 109.

In the semiconductor structure SS, an ion implantation region IIA (a high-resistance region) is formed as a current confinement region having an annular light-emitting region setting part that sets a light-emitting region 104a of the active layer 104. The ion implantation region IIA is formed in a peripheral part of the cladding layer 105, the tunnel junction layer 106, and the cladding layer 107, for example. Note that the ion implantation region IIA may be formed in only the cladding layer 107 and the tunnel junction layer 106, for example.

### Substrate

The substrate 101 is an InP substrate, for example.

### First Reflector

The first reflector 102 is a semiconductor multilayer reflector (a semiconductor DBR), for example. The semiconductor multilayer reflector has a structure in which a plurality of types (e.g., two types) of refractive index layers (semiconductor layers) having different refractive indices from each other are alternately layered at an optical thickness of ¼ of the oscillation wavelength λ (λ/4). The semiconductor multilayer reflector serving as the first reflector 102 is formed from a compound semiconductor in which a pair of refractive index layers is lattice-matched to InP, such as InP/AlGaInAs, AlInAs/AlGaInAs, or the like, for example.

### Active Layer

The active layer 104 is formed from a compound semiconductor that is lattice-matched to InP, such as InGaAsP, AlGaInAs, InAS, or the like, for example. The active layer 104 has a single quantum well structure (QW structure) or a multiple quantum well structure (MQW structure) including a barrier layer and a quantum well layer. Note that the active layer 104 may be an InGaAs-based quantum dot active layer, for example. The active layer 104 is preferably designed to handle long wavelengths at at least the oscillation wavelength A of 900 nm, and more preferably, at least 1.3 μm, for example. For example, in the active layer 104, a region corresponding to the region surrounded by the ion implantation region IIA of the semiconductor structure SS (a low-resistance region) corresponds to the light-emitting region 104a.

### Second Reflector

The second reflector 108 is, for example, a dielectric multilayer reflector (dielectric DBR), and has a structure in which a plurality of types (e.g., two types) of refractive index layers (dielectric layers) having different refractive indices from each other are alternately layered at an optical thickness of ¼ of the oscillation wavelength λ (λ/4).

The dielectric multilayer reflector serving as the second reflector 108 is set to have a slightly lower reflectance than the semiconductor multilayer reflector serving as the first reflector 102, and is a reflector on the emitting side. In other words, the surface-emitting laser 10-1 is a front surface-emitting type of surface-emitting laser that emits light on the front surface side (top surface side) of the substrate 101. Note that because the reflectance of the dielectric multilayer reflector serving as the second reflector 108 is set to be slightly higher than the reflectance of the semiconductor multilayer reflector serving as the first reflector 102, the surface-emitting laser 10-1 can also be configured as a rear surface-emitting type of surface-emitting laser that uses the first reflector 102 as the reflector on the emitting side.

The pair of refractive index layers of the dielectric multilayer reflector serving as the second reflector 108 is, for example, SiO₂/TiO₂, SiO₂/Ta₂O₅, SiO₂/SiN, SiO₂/a-Si, Al₂O₃/a-Si, or the like. Note that the second reflector 108 may include a multilayer reflector other than a dielectric multilayer reflector, such as a semiconductor multilayer reflector, for example.

### Insulating Film

The insulating film 109 is constituted by a dielectric such as SiO₂, SiN, SiON, or the like, for example.

### Anode Electrode

The anode electrode 110 is formed from Au/Ni/AuGe, Au/Pt/Ti, or the like, for example. The anode electrode 110 is electrically connected to the anode (positive terminal) of the laser driver, for example.

### Cathode Electrode

The cathode electrode 111 is formed from Au/Ni/AuGe, Au/Pt/Ti, or the like, for example. The cathode electrode 111 is electrically connected to the cathode (negative terminal) of the laser driver, for example.

### Semiconductor Structure

### Cladding Layer

The cladding layer 105 is formed from a p-type semiconductor layer (e.g., a p-InP layer). The cladding layer 107 is formed from an n-type semiconductor layer (e.g., an n-InP layer). In other words, a surface layer including the top surface of the cladding layer 107 is formed from n-InP, for example.

### Tunnel Junction Layer

The tunnel junction layer 106 is responsible for converting injected electrons from the cladding layer 107, which is the adjacent n-type semiconductor layer, into holes and injecting the holes into the cladding layer 105, which is the adjacent p-type semiconductor layer. The tunnel junction layer 106 includes a p-type semiconductor region 106a and an n-type semiconductor region 106b disposed in contact with each other. Here, the p-type semiconductor region 106a is disposed on the active layer 104 side (the lower side) of the n-type semiconductor region 106b. The p-type semiconductor region 106a is formed from, for example, a p-type InP-based compound semiconductor or an AlGaInAs-based compound semiconductor highly doped with C, Mg, or Zn. The n-type semiconductor region 106b is formed from, for example, an InP-based compound semiconductor or an AlGaInAs-based compound semiconductor highly doped with Si.

As illustrated in FIG. 1 and FIG. 2, the semiconductor structure SS is provided with an annular step part 107a1 in the front surface on the second reflector 108 side (e.g., the top surface of the cladding layer 107). Here, “annular step part” refers to a step part that is annular (an annularly-shaped step part). The annular step part 107a1 is a step part on the inner side of an annular groove 107a provided in the top surface of the cladding layer 107. Here, the annular groove 107a is constituted by an air layer, for example. In plan view (seen from a layering direction (the vertical direction)), the annular groove 107a and the annular step part 107a1 are annular in shape, for example.

For example, in plan view, the annular step part 107a1 surrounds a center 104a1 of the light-emitting region 104a of the active layer 104 (see FIG. 2). In plan view, the annular step part 107a1 extends along an inner peripheral edge IIAa of the light-emitting region setting part of the ion implantation region IIA. To be more specific, for example, in plan view, the annular step part 107a1 extends while overlapping with the inner peripheral edge IIAa of the light-emitting region setting part of the ion implantation region IIA.

In plan view, an optical distance OD1, in the layering direction (the vertical direction), of the region surrounded by the annular step part 107a1 of the semiconductor structure SS is longer than an optical distance OS2, in the layering direction, of the region provided with the annular step part 107a1 of the semiconductor structure SS, resulting in an effective refractive index difference of Δn (1×10⁻³ or more). In other words, the annular step part 107a1 functions as a light confinement structure. The base surface of the annular step part 107a1 (the base surface of the annular groove 107a) is located within the cladding layer 107, for example.

### Operations of Surface-Emitting Laser

In the surface-emitting laser 10-1, current flowing from the anode side of the laser driver into the cladding layer 107 via the anode electrode 110 is injected into the active layer 104 through the tunnel junction layer 106 and the cladding layer 105 in that order while being confined by the ion implantation region IIA. At this time, the active layer 104 emits light, and when the light travels back and forth between the first and second reflectors 102 and 108 while being confined by the annular step part 107a1 and amplified by the active layer 104, and oscillation conditions are met, the light is emitted as laser light from the second reflector 108. The current injected into the active layer 104 flows into the cathode side of the laser driver through the cladding layer 103 and the cathode electrode 111 in that order.

### Method for Manufacturing Surface-Emitting Laser

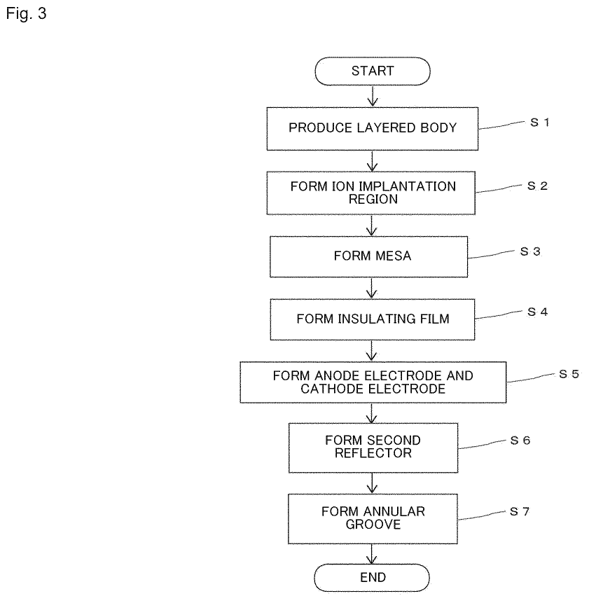

A method for manufacturing the surface-emitting laser 10-1 will be described hereinafter with reference to the flowchart in FIG. 3 and the like. Here, for example, a plurality of surface-emitting lasers 10-1 are produced simultaneously on a single wafer, which serves as the substrate 101, by a semiconductor manufacturing method using a semiconductor manufacturing device. The integrated plurality of surface-emitting lasers 10-1 are then separated to obtain the plurality of surface-emitting lasers 10-1 in chip form (surface-emitting laser chips).

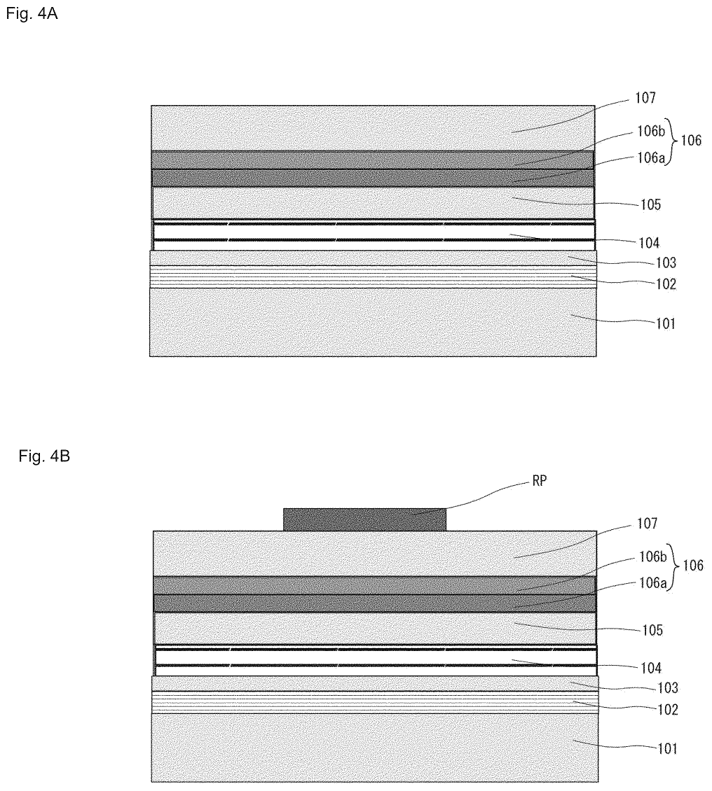

In the first step, step S1, a layered body is produced (see FIG. 4A). Specifically, for example, the first reflector 102, the cladding layer 103, the active layer 104, the cladding layer 105, the tunnel junction layer 106, and the cladding layer 107 are layered on the substrate 101 (e.g., the InP substrate) in that order in a growth chamber through metal-organic vapor deposition (MOCVD) or molecular beam epitaxy (MBE), and the layered body is formed.

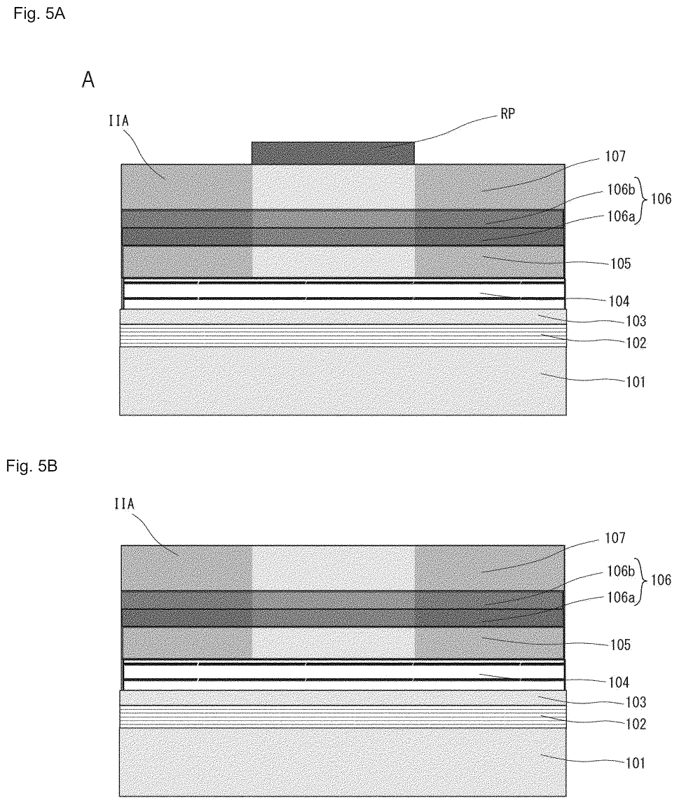

In the next step, step S2, the ion implantation region IIA is formed. Specifically, a resist pattern RP covering the location where the ion implantation region IIA is not to be formed is first formed on the layered body (see FIG. 4B). Ions (H, He, or the like) are then injected from the first cladding layer 107 side into the layered body using the resist pattern RP as a mask (see FIG. 5A). At this time, the implantation depth of the ions is set such that the ion concentration peaks in the vicinity of the tunnel junction layer 106, for example. After this, the resist pattern RP is removed using an organic solvent or through dry etching using O₂ or CF4 (see FIG. 5B).

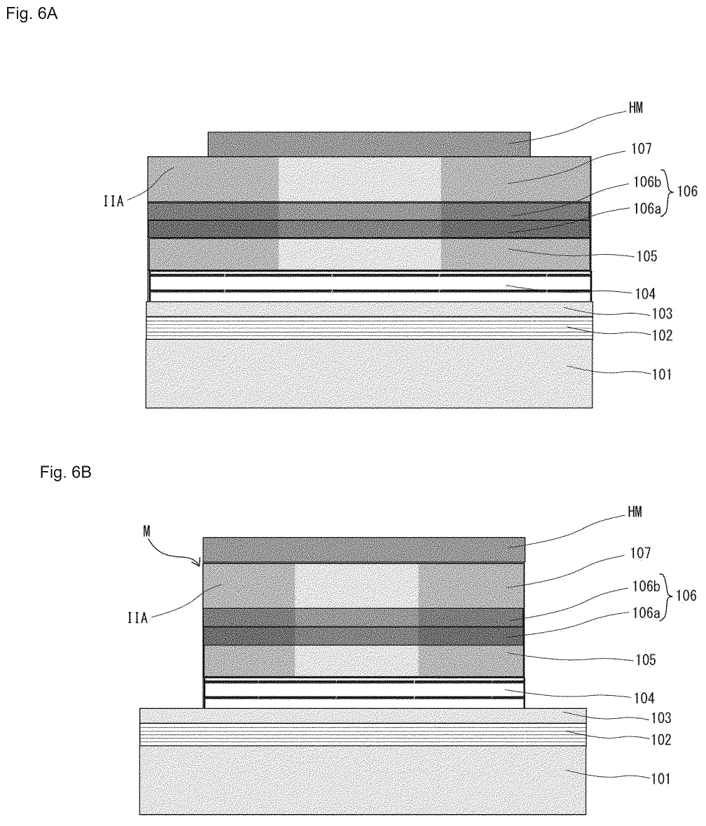

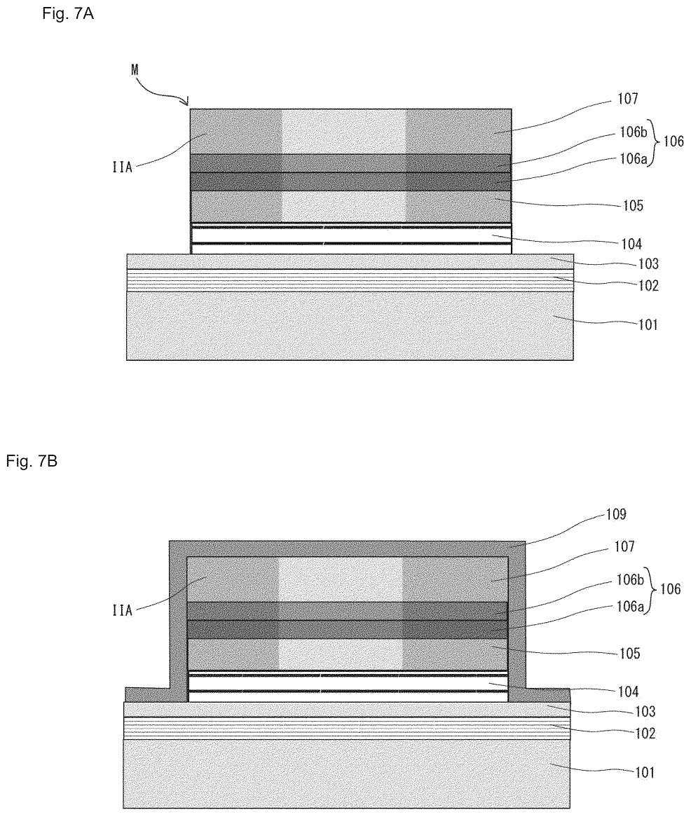

In the next step, step S3, the mesa M is formed. Specifically, a hard mask HM constituted by an oxide film (e.g., a SiO₂ film) is first formed so as to cover the location where the mesa M is to be formed on the layered body where the ion implantation region IIA has been formed (see FIG. 6A). At this time, the oxide film is deposited through CVD, sputtering, deposition, or the like, for example. The oxide film is patterned through photolithography and wet etching using a hydrofluoric acid-based etchant. Then, using the hard mask HM as a mask, the layered body is etched through dry etching using, for example, a Cl-based gas (and specifically, a mixed gas such as Cl₂, BCl₃, SiCl₄, Ar, O₂, or the like, for example), and the mesa M is formed (see FIG. 6B). After this, the hard mask HM is removed through wet etching using a hydrofluoric acid-based etchant (see FIG. 7A).

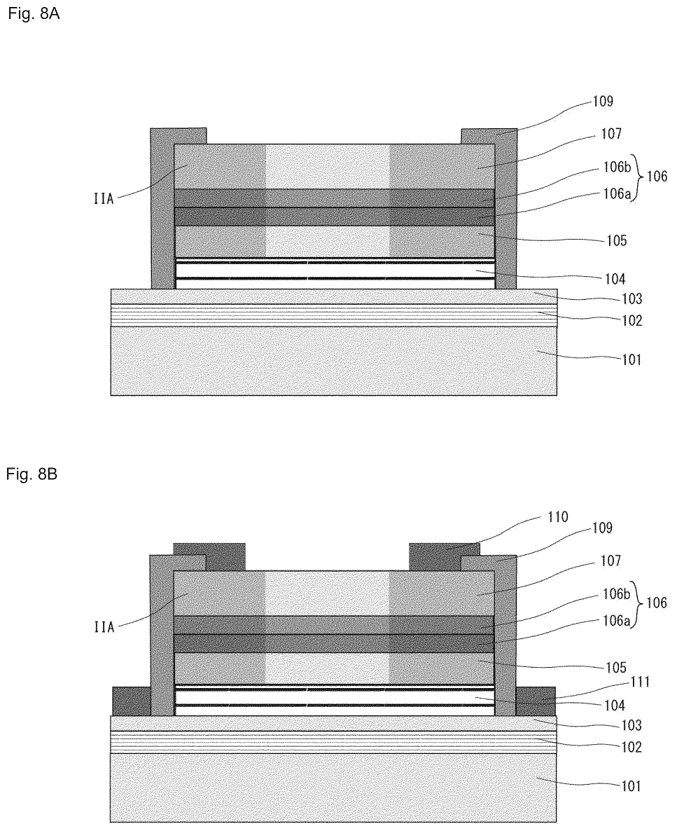

In the next step, step S4, the insulating film 109 is formed. Specifically, the insulating film 109 is first formed on the entire surface of the layered body in which the mesa M is formed, through CVD, for example (see FIG. 7B). Next, a resist pattern covering the side surfaces of the mesa M is formed through photolithography. Then, using the resist pattern as a mask, the insulating film 109 covering the top part and the peripheral regions of the bottom part of the mesa M (the top surface of the cladding layer 103) is removed through dry etching using, for example, CF4 gas (see FIG. 8A). The resist pattern is then removed through etching.

In the next step, step S5, the anode electrode 110 and the cathode electrode 111 are formed (see FIG. 8B). Specifically, the annular anode electrode 110 is formed in the peripheral part of the top part of the mesa M, and the cathode electrode 111 is formed in the peripheral region of the bottom part of the mesa M, through lift-off, for example.

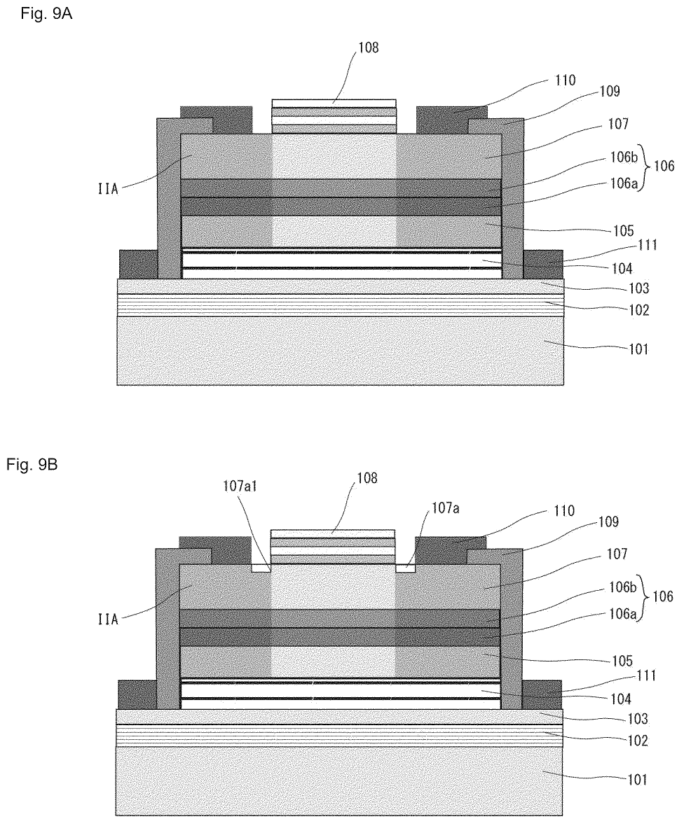

In the next step, step S6, the second reflector 108 is formed (see FIG. 9A). Specifically, a dielectric multilayer film is first formed on the entire surface. Next, a resist pattern is formed through photolithography to cover the part where the second reflector 108 is formed. Next, using the resist pattern as a mask, the dielectric multilayer film is etched to form the dielectric multilayer reflector serving as the second reflector 108. The resist pattern is then removed through etching. Note that the second reflector 108 may be formed using lift-off, for example.

In the final step, step S7, the annular groove 107a is formed (see FIG. 9B). Specifically, a resist pattern covering the locations other than the location where the annular groove 107a is to be formed is first formed through photolithography. Then, using the resist pattern as a mask, the annular groove 107a is formed through dry etching, for example.

### Effects of Surface-Emitting Laser

The surface-emitting laser 10-1 according to Example 1 of the first embodiment of the present technique includes the first and second reflectors 102 and 108, the active layer 104 disposed between the first and second reflectors 102 and 108, and the semiconductor structure SS disposed between the active layer 104 and the second reflector 108. The annular step part 107a1 is provided on the surface of the semiconductor structure SS on the side thereof where the second reflector 108 is located.

In this case, a surface-emitting laser having a light confinement structure, which can be manufactured without epitaxial regrowth (i.e., which can suppress an increase in processing and drops in yield), can be provided.

As a result, according to the surface-emitting laser 10-1, a surface-emitting laser having a light confinement structure, which can reduce manufacturing costs, can be provided.

In addition, the effective refractive index difference Δn is 1×10⁻³ or more, and thus higher output and higher efficiency can be achieved in the surface-emitting laser 10-1.

In the semiconductor structure SS, the ion implantation region IIA is provided as a current confinement region having at least one annular light-emitting region setting part that sets the light-emitting region 104a of the active layer 104, and in plan view, the annular step part 107a1 surrounds the center 104a1 of the light-emitting region 104a. This makes it possible to reliably confine the light from the light-emitting region 104a by the annular step part 107a1.

In plan view, the annular step part 107a1 extends along the inner peripheral edge IIAa of the light-emitting region setting part. This makes it possible to efficiently confine the light generated in the light-emitting region 104a.

In plan view, the annular step part 107a1 extends so as to overlap with the inner peripheral edge IIAa of the light-emitting region setting part. This makes it possible to more efficiently confine the light generated in the light-emitting region 104a.

The semiconductor structure SS includes the cladding layer 107 which has one surface on the second reflector 108 side. This makes it possible to provide the annular step part 107a1 without complicating the layer structure of the semiconductor structure SS.

The base surface of the annular step part 107a1 is located within the cladding layer 107. This makes it possible to form a current path within the cladding layer 107.

A surface layer including one surface of the cladding layer 107 is formed from InP (e.g., n-InP). Through this, the semiconductor structure SS can be formed from a material lattice-matched to InP or InP. Furthermore, the surface-emitting laser 10-1 uses a material that is lattice-matched to InP for the active layer 104, and it is therefore possible to realize a long wavelength-band VCSEL having an oscillation wavelength λ of 900 nm or more.

In addition to the cladding layer 107 (e.g., the n-type semiconductor layer), the semiconductor structure SS includes the cladding layer 105 (e.g., the p-type semiconductor layer) disposed between the cladding layer 107 and the active layer 104, and the tunnel junction layer 106 disposed between the cladding layer 107 and the cladding layer 105. Furthermore, the cladding layer 103 (an n-type semiconductor) is disposed on the side of the active layer 104 opposite from the side on which the semiconductor structure SS is located. This makes it possible to lower the operating voltage and efficiently inject current into the active layer 104.

Incidentally, there is also a surface-emitting laser in which a GaAs epitaxial wafer having an oxidation confinement structure is heterogeneously bonded to an InP-based wafer. However, in this surface-emitting laser, at least two types of heterogeneous substrates (a GaAs substrate and an InP substrate) are required, resulting in problems in that an additional bonding process is required, and the yield and reliability are worsened. To avoid this problem, a surface-emitting laser having an intracavity structure in which oxidation in an InAlAs layer is confined has also been developed. However, the oxidation rate of InAlAs is significantly slower than the oxidation rate of AlAs used in GaAs-based materials, which not only worsened the yield, but also meant that the structure itself could not realistically be manufactured.

### 2. Surface-Emitting Laser According to Example 2 of First Embodiment of Present Technique

A surface-emitting laser according to Example 2 of the first embodiment of the present technique will be described hereinafter.

### Configuration of Surface-Emitting Laser

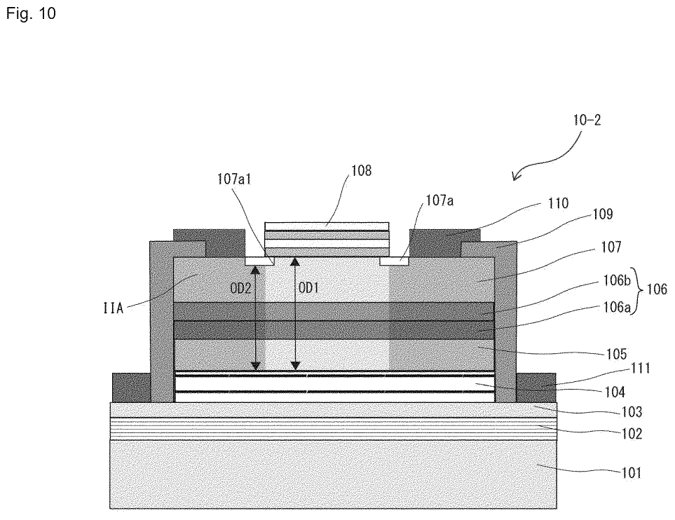

FIG. 10 is a cross-sectional view of a surface-emitting laser 10-2 according to Example 2 of the first embodiment of the present technique.

As illustrated in FIG. 10, the surface-emitting laser 10-2 has the same configuration as the surface-emitting laser 10-1 according to Example 1, except that in plan view, the annular step part 107a1 extends within the inner peripheral edge of the light-emitting region setting part of the ion implantation region IIA.

In the surface-emitting laser 10-2, in plan view, the annular step part 107a1 extends approximately several nm to 2 um on the inner peripheral edge of the light-emitting region setting part of the ion implantation region IIA (i.e., to an extent that does not affect laser oscillation).

### Operations of Surface-Emitting Laser

The surface-emitting laser 10-2 performs the same operations as the surface-emitting laser 10-1 according to Example 1.

### Method for Manufacturing Surface-Emitting Laser

The surface-emitting laser 10-2 can be manufactured through a manufacturing method similar to the method for manufacturing the surface-emitting laser 10-1 according to Example 1. However, in the method for manufacturing the surface-emitting laser 10-2, side etching is increased by wet etching when forming the annular step part 107a1. This makes it possible to form the annular step part 107a1 inside of the inner peripheral edge of the light-emitting region setting part. A mixed solution such as hydrochloric acid, phosphoric acid, acetic acid, water, or the like, for example, can be used as the etchant for the wet etching of the cladding layer 107 (the n-InP layer).

### Effects of Surface-Emitting Laser

According to the surface-emitting laser 10-2, generally the same effects as the surface-emitting laser 10-1 according to Example 1 can be achieved.

### 3. Surface-Emitting Laser According to Example 3 of First Embodiment of Present Technique

A surface-emitting laser according to Example 3 of the first embodiment of the present technique will be described hereinafter.

### Configuration of Surface-Emitting Laser

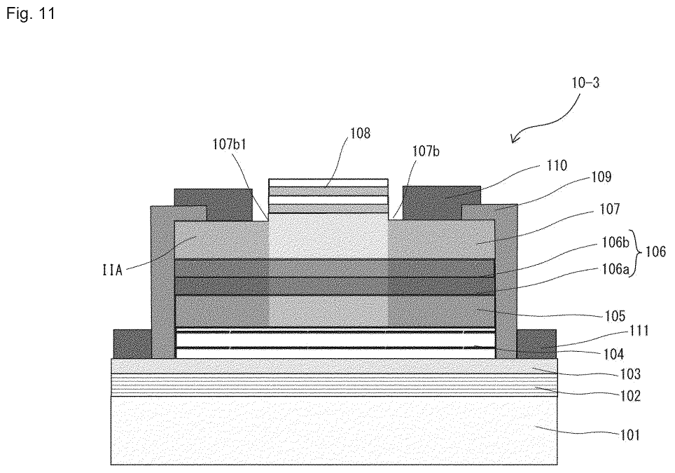

FIG. 11 is a cross-sectional view of a surface-emitting laser 10-3 according to Example 3 of the first embodiment of the present technique.

As illustrated in FIG. 11, the surface-emitting laser 10-3 has the same configuration as the surface-emitting laser 10-1 according to Example 1, except that an annular step part 107b1 is a step part (a corner) of an annular notch 107b.

### Operations of Surface-Emitting Laser

The surface-emitting laser 10-3 performs the same operations as the surface-emitting laser 10-1 according to Example 1.

### Method for Manufacturing Surface-Emitting Laser

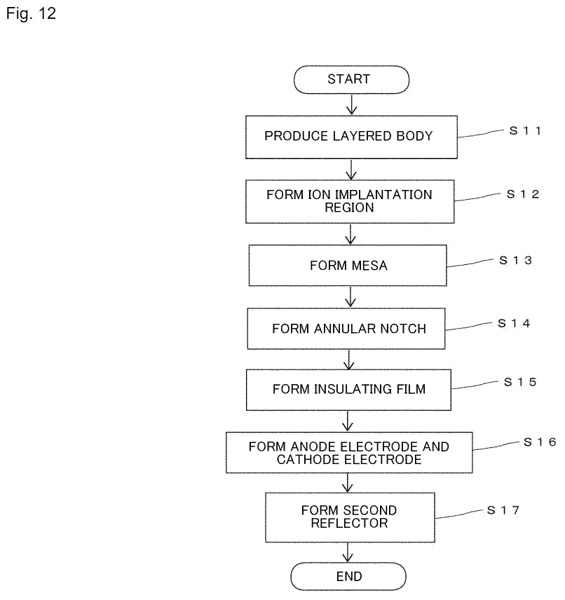

A method for manufacturing the surface-emitting laser 10-3 will be described hereinafter with reference to the flowchart in FIG. 12 and the like. Here, for example, a plurality of surface-emitting lasers 10-3 are produced simultaneously on a single wafer, which serves as the substrate 101, by a semiconductor manufacturing method using a semiconductor manufacturing device. The integrated plurality of surface-emitting lasers 10-3 are then separated to obtain the plurality of surface-emitting lasers 10-3 in chip form (surface-emitting laser chips).

In the first step, step S11, a layered body is produced (see FIG. 4A). Specifically, for example, the first reflector 102, the cladding layer 103, the active layer 104, the cladding layer 105, the tunnel junction layer 106, and the cladding layer 107 are layered on the substrate 101 (e.g., the InP substrate) in that order in a growth chamber through metal-organic vapor deposition (MOCVD) or molecular beam epitaxy (MBE), and the layered body is formed.

In the next step, step S12, the ion implantation region IIA is formed. Specifically, a resist pattern RP covering the location where the ion implantation region IIA is not to be formed is first formed on the layered body (see FIG. 4B). Ions (H, He, or the like) are then injected from the first cladding layer 107 side into the layered body using the resist pattern RP as a mask (see FIG. 5A). At this time, the implantation depth of the ions is set such that the ion concentration peaks in the vicinity of the tunnel junction layer 106, for example. After this, the resist pattern RP is removed using an organic solvent or through dry etching using O₂ or CF4 (see FIG. 5B).

In the next step, step S13, the mesa M is formed. Specifically, a hard mask HM constituted by an oxide film (e.g., a SiO₂ film) is first formed so as to cover the location where the mesa M is to be formed on the layered body where the ion implantation region IIA has been formed (see FIG. 6A). At this time, the oxide film is deposited through CVD, sputtering, deposition, or the like, for example. The oxide film is patterned through photolithography and wet etching using a hydrofluoric acid-based etchant. Then, using the hard mask HM as a mask, the layered body is etched through dry etching using, for example, a Cl-based gas (and specifically, a mixed gas such as Cl₂, BCl₃, SiCl₄, Ar, O₂, or the like, for example), and the mesa M is formed (see FIG. 6B). After this, the hard mask HM is removed through wet etching using a hydrofluoric acid-based etchant (see FIG. 7A).

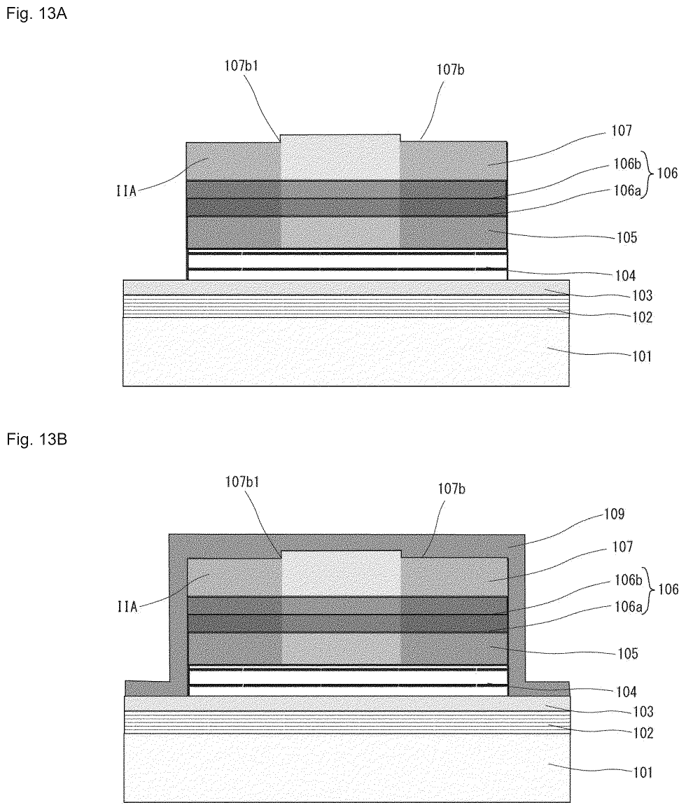

In the next step, step S14, the annular notch 107b is formed (see FIG. 13A). Specifically, a resist pattern covering the locations other than the location where the notch 107b is to be formed is first formed through photolithography. Then, the notch 107b is formed through etching (dry etching or wet etching) using the resist pattern as a mask.

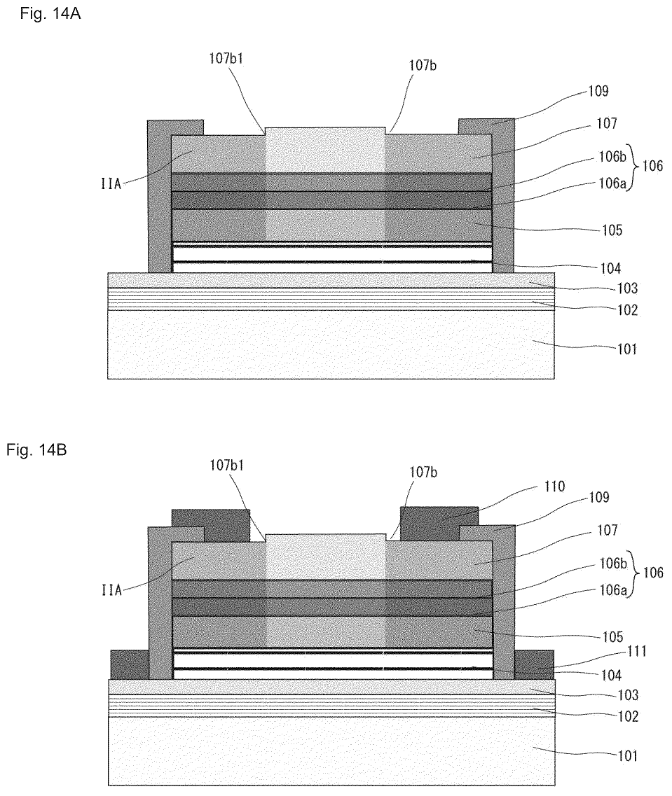

In the next step, step S15, the insulating film 109 is formed. Specifically, the insulating film 109 is first formed on the entire surface of the layered body in which the notch 107b is formed, through CVD, for example (see FIG. 13B). Next, a resist pattern covering the side surfaces of the mesa M is formed through photolithography. Then, using the resist pattern as a mask, the insulating film 109 covering the top part and the peripheral regions of the bottom part of the mesa M (the top surface of the cladding layer 103) is removed through dry etching using, for example, CF₄ gas (see FIG. 14A). The resist pattern is then removed through etching.

In the next step, step S16, the anode electrode 110 and the cathode electrode 111 are formed (see FIG. 14B). Specifically, the annular anode electrode 110 is formed in the peripheral part of the top part of the mesa M, and the cathode electrode 111 is formed in the peripheral region of the bottom part of the mesa M, through lift off, for example.

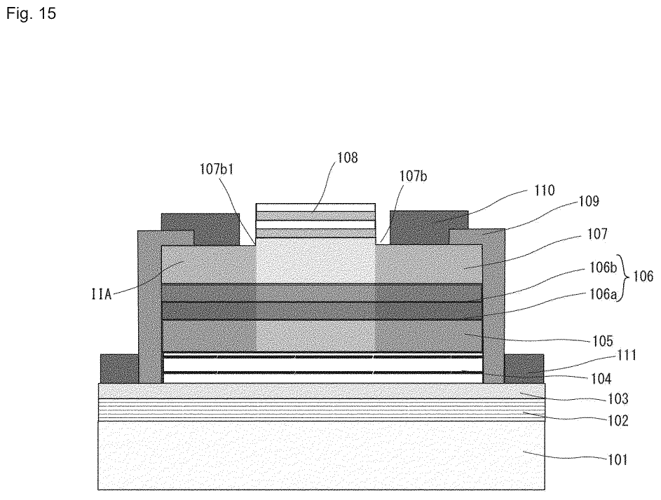

In the final step, step S17, the second reflector 108 is formed (see FIG. 15). Specifically, a dielectric multilayer film is first formed on the entire surface. Next, a resist pattern is formed through photolithography to cover the part where the second reflector 108 is formed. Next, using the resist pattern as a mask, the dielectric multilayer film is etched to form the dielectric multilayer reflector serving as the second reflector 108. The resist pattern is then removed through etching. Note that the second reflector 108 may be formed using lift-off, for example.

### Effects of Surface-Emitting Laser

According to the surface-emitting laser 10-3, the same effects as the surface-emitting laser 10-1 according to Example 1 can be achieved.

### 4. Surface-Emitting Laser According to Example 4 of First Embodiment of Present Technique

A surface-emitting laser according to Example 4 of the first embodiment of the present technique will be described hereinafter.

### Configuration of Surface-Emitting Laser

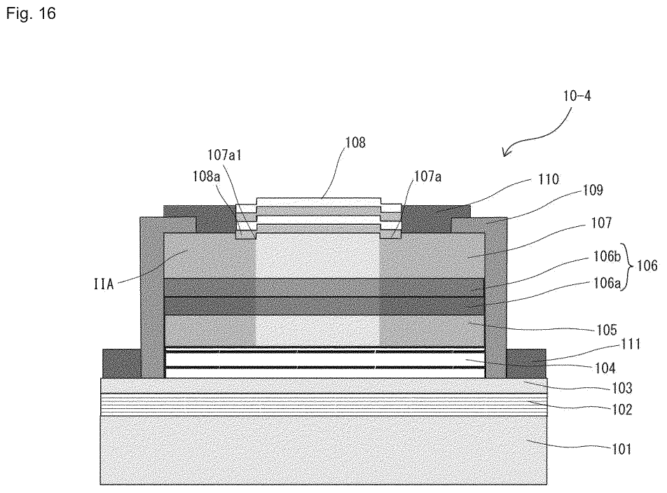

FIG. 16 is a cross-sectional view of a surface-emitting laser 10-4 according to Example 4 of the first embodiment of the present technique.

As illustrated in FIG. 16, the surface-emitting laser 10-4 has the same configuration as the surface-emitting laser 10-1 according to Example 1, except that an annular low refractive index layer 108a having a lower refractive index than that of the cladding layer 107 is provided in contact with the annular step part 107a1 so as to surround the annular step part 107a1.

The low refractive index layer 108a is constituted by a dielectric. Specifically, the low refractive index layer 108a is one layer of the pair of dielectric multilayer reflectors serving as the second reflector 108. Specifically, when the dielectric multilayer reflector has a pair such as, for example, SiO₂/TiO₂, SiO₂/Ta₂O₅, SiO₂/SiN, SiO₂/a-Si, or the like, the low refractive index layer 108a can be any one of SiO₂, TiO₂, Ta₂O₅, SiN, or a-Si. However, from the viewpoint of increasing the effective refractive index difference Δn, it is preferable that the low refractive index layer 108a be SiO₂. When the dielectric multilayer reflector has a pair such as, for example, Al₂O₃/a-Si or the like, the low refractive index layer 108a can be either Al₂O₃ or a-Si. However, from the viewpoint of increasing the effective refractive index difference Δn, it is preferable that the low refractive index layer 108a be Al₂O₃.

### Operations of Surface-Emitting Laser

The surface-emitting laser 10-4 performs the same operations as the surface-emitting laser 10-1 according to Example 1.

### Method for Manufacturing Surface-Emitting Laser

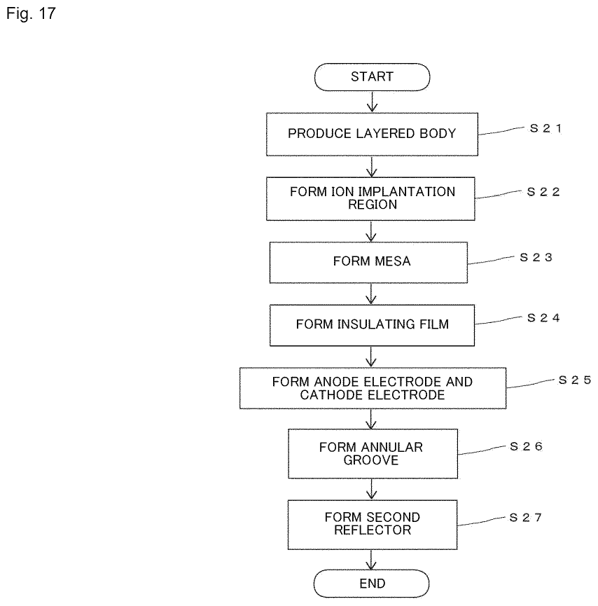

A method for manufacturing the surface-emitting laser 10-4 will be described hereinafter with reference to the flowchart in FIG. 17 and the like. Here, for example, a plurality of surface-emitting lasers 10-4 are produced simultaneously on a single wafer, which serves as the substrate 101, by a semiconductor manufacturing method using a semiconductor manufacturing device. The integrated plurality of surface-emitting lasers 10-4 are then separated to obtain the plurality of surface-emitting lasers 10-4 in chip form (surface-emitting laser chips).

In the first step, step S21, a layered body is produced (see FIG. 4A). Specifically, for example, the first reflector 102, the cladding layer 103, the active layer 104, the cladding layer 105, the tunnel junction layer 106, and the cladding layer 107 are layered on the substrate 101 (e.g., the InP substrate) in that order in a growth chamber through metal-organic vapor deposition (MOCVD) or molecular beam epitaxy (MBE), and the layered body is formed.

In the next step, step S22, the ion implantation region IIA is formed. Specifically, a resist pattern RP covering the location where the ion implantation region IIA is not to be formed is first formed on the layered body (see FIG. 4B). Ions (H, He, or the like) are then injected from the first cladding layer 107 side into the layered body using the resist pattern RP as a mask (see FIG. 5A). At this time, the implantation depth of the ions is set such that the ion concentration peaks in the vicinity of the tunnel junction layer 106, for example. After this, the resist pattern RP is removed using an organic solvent or through dry etching using O₂ or CF4 (see FIG. 5B).

In the next step, step S23, the mesa M is formed. Specifically, a hard mask HM constituted by an oxide film (e.g., a SiO₂ film) is first formed so as to cover the location where the mesa M is to be formed on the layered body where the ion implantation region IIA has been formed (see FIG. 6A). At this time, the oxide film is deposited through CVD, sputtering, deposition, or the like, for example. The oxide film is patterned through photolithography and wet etching using a hydrofluoric acid-based etchant. Then, using the hard mask HM as a mask, the layered body is etched through dry etching using, for example, a Cl-based gas (and specifically, a mixed gas such as Cl₂, BCl₃, SiCl₄, Ar, O₂, or the like, for example), and the mesa M is formed (see FIG. 6B). After this, the hard mask HM is removed through wet etching using a hydrofluoric acid-based etchant (see FIG. 7A).

In the next step, step S24, the insulating film 109 is formed. Specifically, the insulating film 109 is first formed on the entire surface of the layered body in which the mesa M is formed, through CVD, for example (see FIG. 7B). Next, a resist pattern covering the side surfaces of the mesa M is formed through photolithography. Then, using the resist pattern as a mask, the insulating film 109 covering the top part and the peripheral regions of the bottom part of the mesa M (the top surface of the cladding layer 103) is removed through dry etching using, for example, CF4 gas (see FIG. 8A). The resist pattern is then removed through etching.

In the next step, step S25, the anode electrode 110 and the cathode electrode 111 are formed (see FIG. 8B). Specifically, the annular anode electrode 110 is formed in the peripheral part of the top part of the mesa M, and the cathode electrode 111 is formed in the peripheral region of the bottom part of the mesa M, through lift-off, for example.

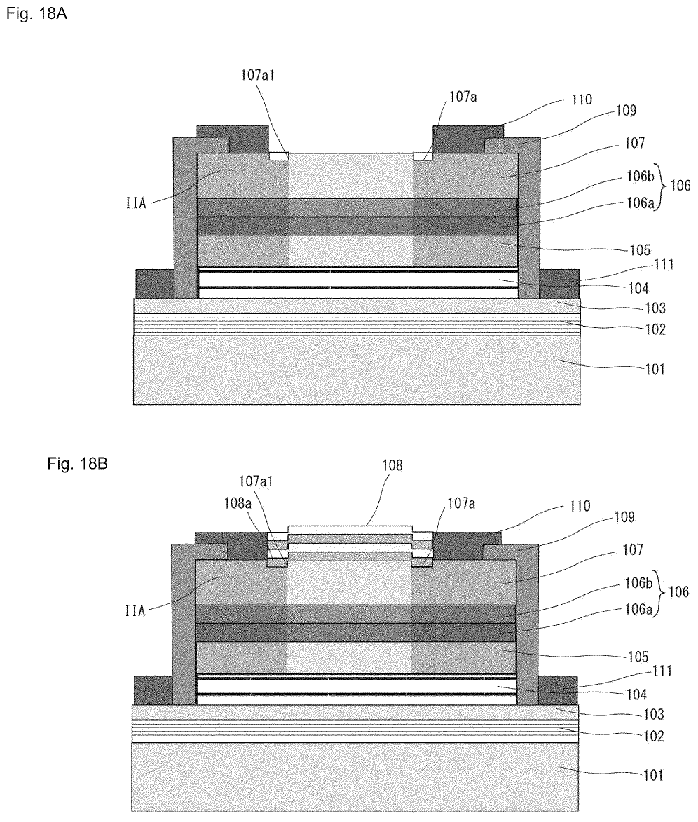

In the next step, step S26, the annular groove 107a is formed (see FIG. 18A). Specifically, a resist pattern covering the locations other than the location where the annular groove 107a is to be formed is first formed through photolithography. Then, using the resist pattern as a mask, the annular groove 107a is formed through dry etching, for example.

In the next step, step S27, the second reflector 108 is formed (see FIG. 18B). Specifically, a dielectric multilayer film is first formed on the entire surface. At this time, the dielectric multilayer film is formed such that the low refractive index layer 108a (one of the layers in the dielectric multilayer film pair) is formed first. The annular low refractive index layer 108a is formed in contact with the annular step part 107a1 as a result. Next, a resist pattern is formed through photolithography to cover the part where the second reflector 108 is formed. Next, using the resist pattern as a mask, the dielectric multilayer film is etched to form the dielectric multilayer reflector serving as the second reflector 108. The resist pattern is then removed through etching. Note that the second reflector 108 may be formed using lift off, for example.

### Effects of Surface-Emitting Laser

According to the surface-emitting laser 10-4, generally the same effects as the surface-emitting laser 10-1 according to Example 1 can be achieved.

### 5. Surface-Emitting Laser According to Example 5 of First Embodiment of Present Technique

A surface-emitting laser according to Example 5 of the first embodiment of the present technique will be described hereinafter.

### Configuration of Surface-Emitting Laser

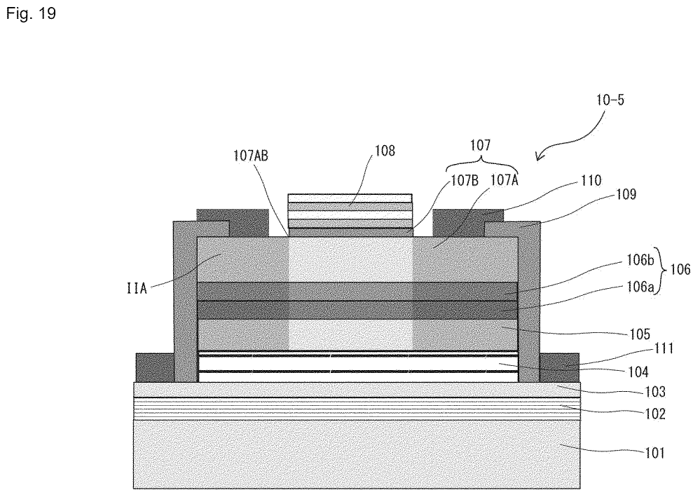

FIG. 19 is a cross-sectional view of a surface-emitting laser 10-5 according to Example 5 of the first embodiment of the present technique.

As illustrated in FIG. 19, the surface-emitting laser 10-5 has the same configuration as the surface-emitting laser 10-1 according to Example 1, except that the surface layer of the cladding layer 107 on the second reflector 108 side is constituted by InP and a material lattice-matched with InP.

Incidentally, the central part corresponding to the light-emitting region of the cladding layer 107 on the second reflector 108 side may be made of a material transparent with respect to the oscillation wavelength λ, and is not limited to InP.

In the surface-emitting laser 10-5, for example, in the surface layer of the cladding layer 107 on the second reflector 108 side, a peripheral part corresponding to the light-emitting region setting part of the ion implantation region IIA is constituted by part of an InP layer 107A (e.g., an n-InP layer), and a central part surrounded by the light-emitting region setting part of the ion implantation region IIA is constituted by a mixed crystal layer 107B formed from a material lattice-matched to InP (e.g., mixed crystals such as InGaAsP, AlGaInAs, or the like). In particular, using InGaAsP for the material of the mixed crystal layer 107B enables the layer to also function as an etching stop layer. Here, the cladding layer 107 has a two-layer structure in which the mixed crystal layer 107B, which is substantially annular in plan view, is layered on the InP layer 107A. An annular step part 107AB is formed by the InP layer 107A and the mixed crystal layer 107B.

### Operations of Surface-Emitting Laser

The surface-emitting laser 10-5 performs the same operations as the surface-emitting laser 10-1 according to Example 1.

### Method for Manufacturing Surface-Emitting Laser

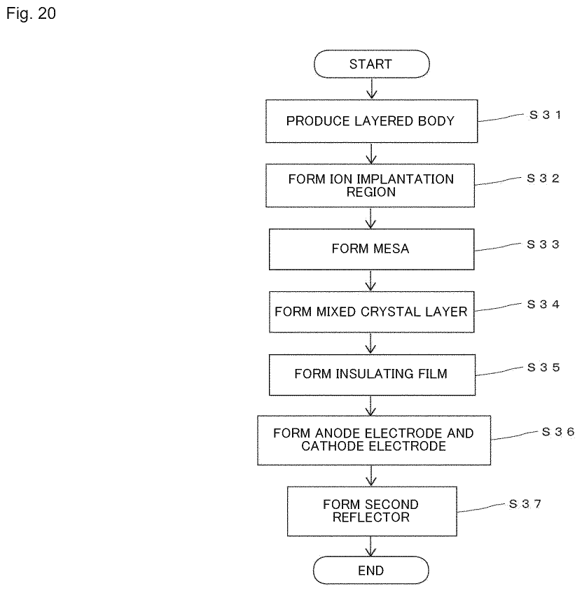

A method for manufacturing the surface-emitting laser 10-5 will be described hereinafter with reference to the flowchart in FIG. 20 and the like. Here, for example, a plurality of surface-emitting lasers 10-5 are produced simultaneously on a single wafer, which serves as the substrate 101, by a semiconductor manufacturing method using a semiconductor manufacturing device. The integrated plurality of surface-emitting lasers 10-5 are then separated to obtain the plurality of surface-emitting lasers 10-5 in chip form (surface-emitting laser chips).

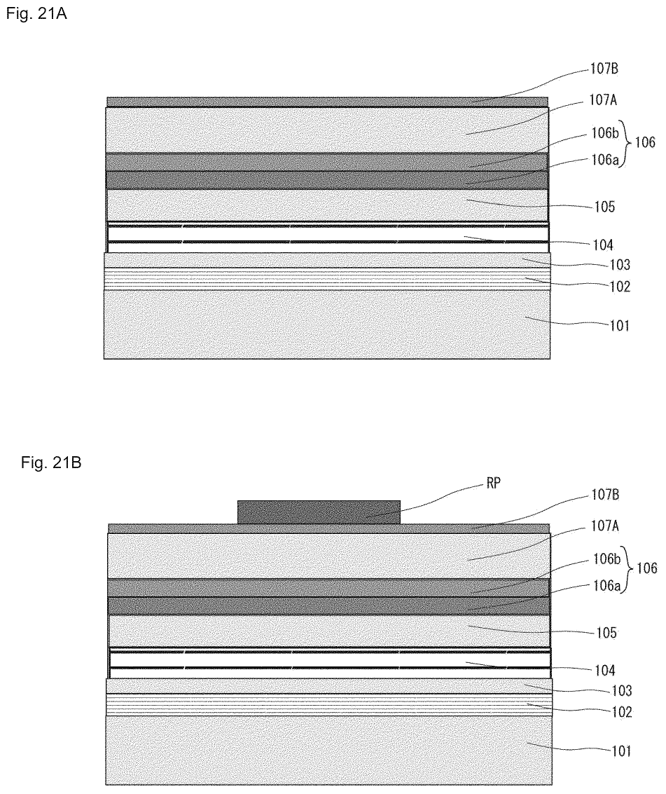

In the first step, step S31, a layered body is produced (see FIG. 21A). Specifically, for example, the first reflector 102, the cladding layer 103, the active layer 104, the cladding layer 105, the tunnel junction layer 106, the n-In layer 107A, and the mixed crystal layer 107B are layered on the substrate 101 (e.g., the InP substrate) in that order in a growth chamber through metal-organic vapor deposition (MOCVD) or molecular beam epitaxy (MBE), and the layered body is formed.

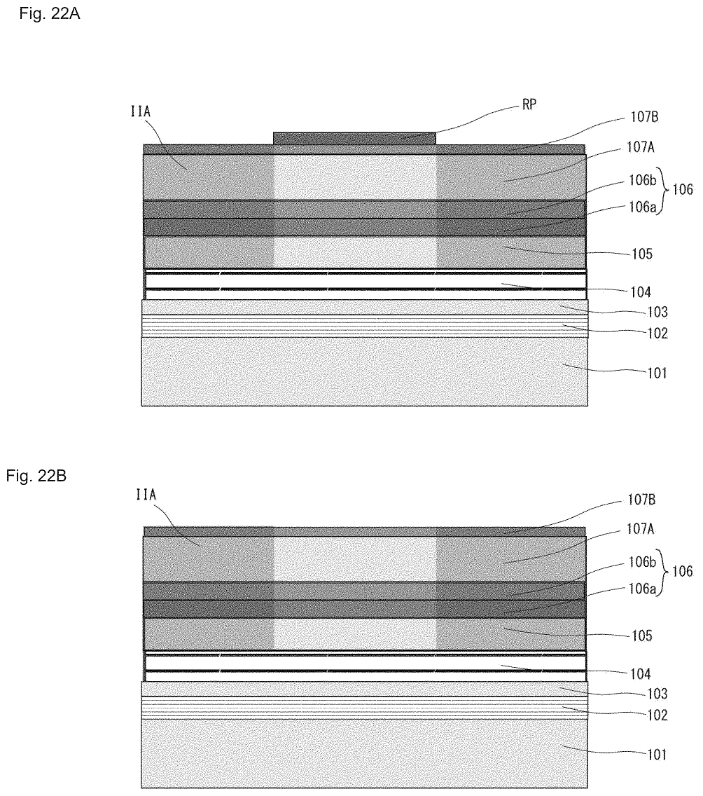

In the next step, step S32, the ion implantation region IIA is formed. Specifically, a resist pattern RP covering the location where the ion implantation region IIA is not to be formed is first formed on the layered body (see FIG. 21B). Ions (H, He, or the like) are then injected from the first cladding layer 107 side into the layered body using the resist pattern RP as a mask (see FIG. 22A). At this time, the implantation depth of the ions is set such that the ion concentration peaks in the vicinity of the tunnel junction layer 106, for example. After this, the resist pattern RP is removed using an organic solvent or through dry etching using O₂ or CF4 (see FIG. 22B).

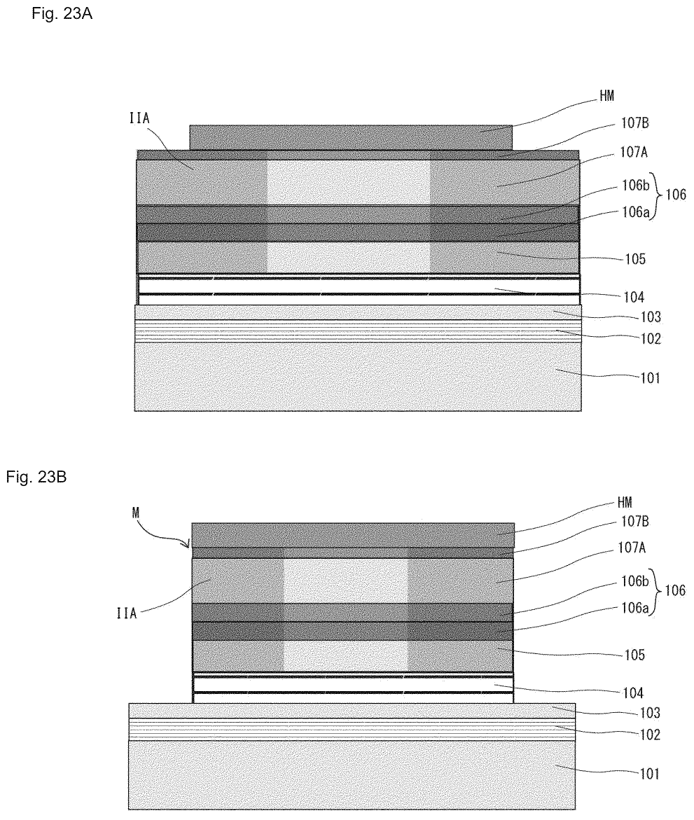

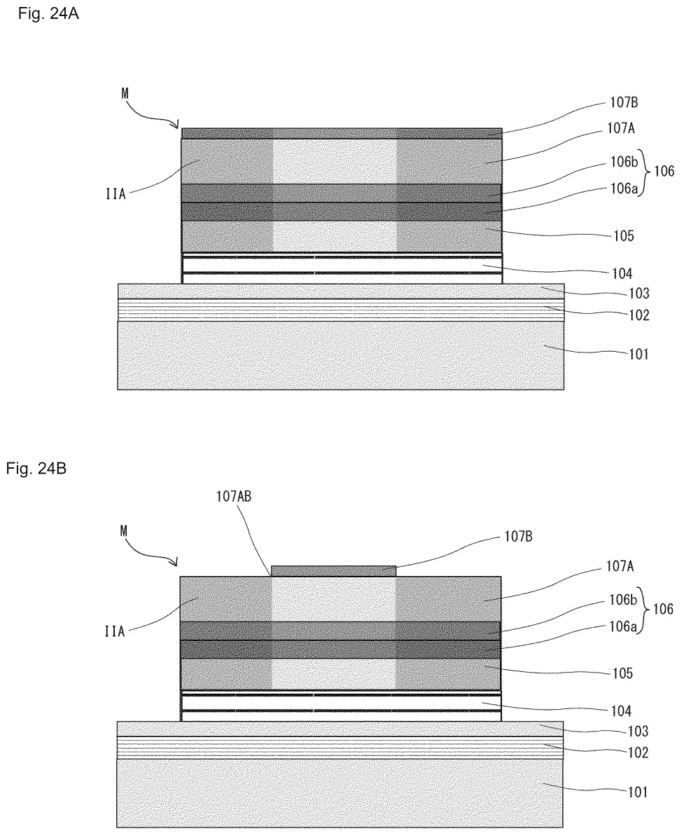

In the next step, step S33, the mesa M is formed. Specifically, a hard mask HM constituted by an oxide film (e.g., a SiO₂ film) is first formed so as to cover the location where the mesa M is to be formed on the layered body where the ion implantation region IIA has been formed (see FIG. 23A). At this time, the oxide film is deposited through CVD, sputtering, deposition, or the like, for example. The oxide film is patterned through photolithography and wet etching using a hydrofluoric acid-based etchant. Then, using the hard mask HM as a mask, the layered body is etched through dry etching using, for example, a Cl-based gas (and specifically, a mixed gas such as Cl₂, BCl₃, SiCl₄, Ar, O₂, or the like, for example), and the mesa M is formed (see FIG. 23B). After this, the hard mask HM is removed through wet etching using a hydrofluoric acid-based etchant (see FIG. 24A).

In the next step, step S34, the mixed crystal layer 107B is formed (see FIG. 24B). Specifically, first, a resist pattern covering the region corresponding to the light-emitting region of the mixed crystal layer 107B is formed. Then, using the resist pattern as a mask, the mesa M is etched to form the mixed crystal layer 107B. At this time, if the mixed crystal layer 107B is constituted by InGaAsP, the layer functions as an etching stop layer, which makes it possible to suppress over-etching. As a result, the annular step part 107AB is formed by the InP layer 107A and the mixed crystal layer 107B.

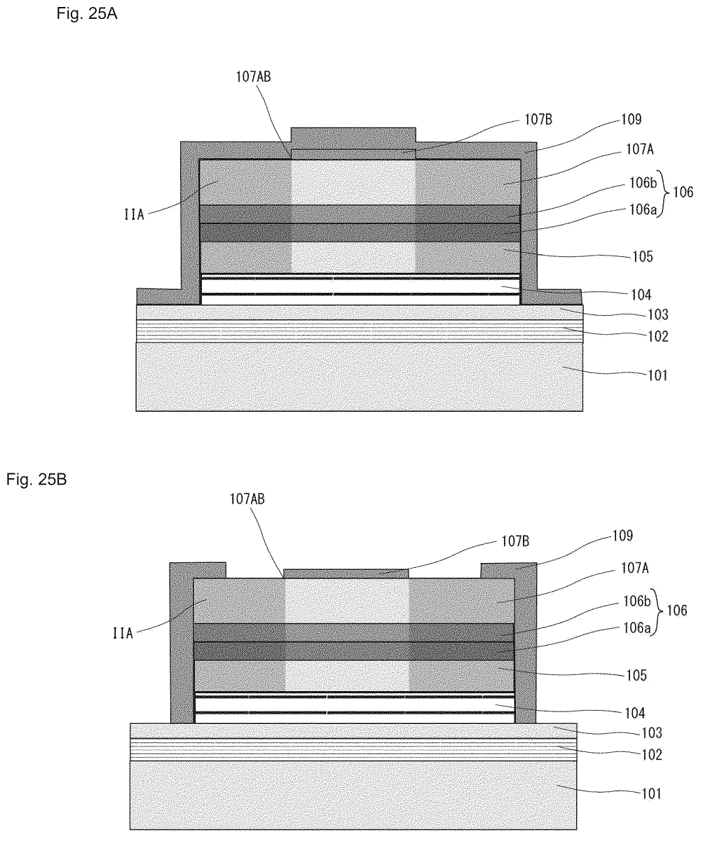

In the next step, step S35, the insulating film 109 is formed. Specifically, the insulating film 109 is first formed on the entire surface of the layered body in which the mixed crystal layer 107B is formed, through CVD, for example (see FIG. 25A). Next, a resist pattern covering the side surfaces of the mesa M is formed through photolithography. Then, using the resist pattern as a mask, the insulating film 109 covering the top part and the peripheral regions of the bottom part of the mesa M (the top surface of the cladding layer 103) is removed through dry etching using, for example, CF4 gas (see FIG. 25B). The resist pattern is then removed through etching.

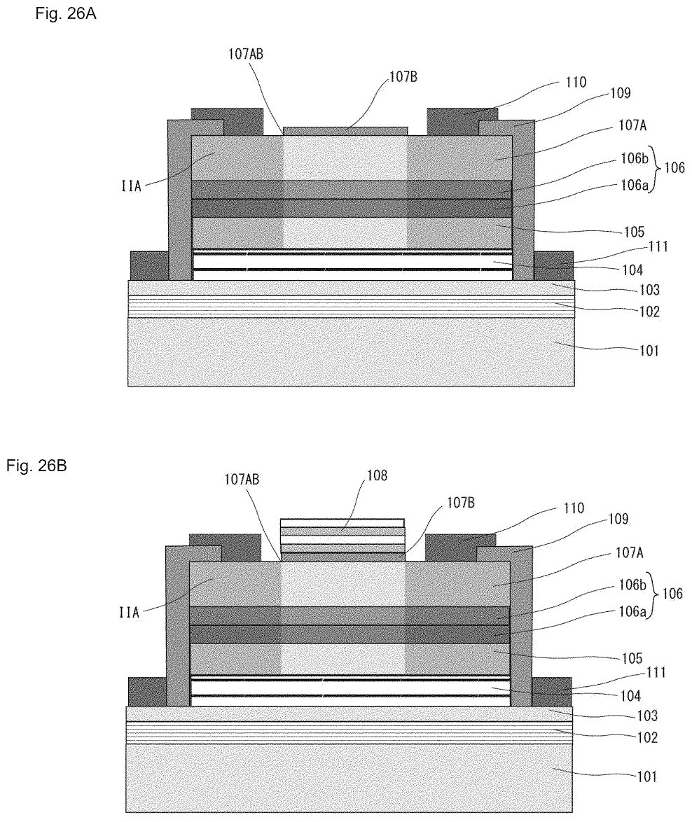

In the next step, step S36, the anode electrode 110 and the cathode electrode 111 are formed (see FIG. 26A). Specifically, the annular anode electrode 110 is formed in the peripheral part of the top part of the mesa M, and the cathode electrode 111 is formed in the peripheral region of the bottom part of the mesa M, through lift-off, for example.

In the final step, step S37, the second reflector 108 is formed (see FIG. 26B). Specifically, a dielectric multilayer film is first formed on the entire surface. Next, a resist pattern is formed through photolithography to cover the part where the second reflector 108 is formed. Next, using the resist pattern as a mask, the dielectric multilayer film is etched to form the dielectric multilayer reflector serving as the second reflector 108. The resist pattern is then removed through etching. Note that the second reflector 108 may be formed using lift-off, for example.

### Effects of Surface-Emitting Laser

According to the surface-emitting laser 10-5, the same effects as the surface-emitting laser 10-1 according to Example 1 can be achieved.

### 6. Surface-Emitting Laser According to Example 6 of First Embodiment of Present Technique

A surface-emitting laser according to Example 6 of the first embodiment of the present technique will be described hereinafter.

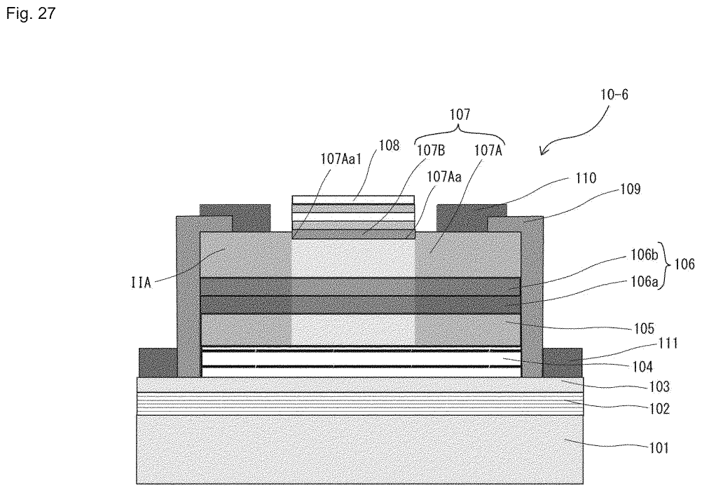

FIG. 27 is a cross-sectional view of a surface-emitting laser 10-6 according to Example 6 of the first embodiment of the present technique.

As illustrated in FIG. 27, the surface-emitting laser 10-6 has the same configuration as the surface-emitting laser 10-1 according to Example 1, except that the surface layer of the cladding layer 107 on the second reflector 108 side is constituted by InP and a material lattice-matched with InP.

In the surface-emitting laser 10-6, for example, in the surface layer of the cladding layer 107 on the second reflector 108 side, a peripheral part corresponding to the light-emitting region setting part of the ion implantation region IIA is constituted by part of an InP layer 107A (e.g., an n-InP layer), and a central part surrounded by the light-emitting region setting part of the ion implantation region IIA is constituted by a mixed crystal layer 107B formed from a material lattice-matched to InP (e.g., mixed crystals such as InGaAsP, AlGaInAs, or the like). In particular, using InGaAsP for the material of the mixed crystal layer 107B enables the layer to also function as an etching stop layer. Here, the cladding layer 107 has a structure in which the mixed crystal layer 107B, which is substantially annular in plan view, is disposed in a recess 107Aa, which is substantially annular in plan view and is provided in the surface of the InP layer 107A on the second reflector 108 side thereof. A step part (corner part) of the recess 107Aa serves as an annular step part 107Aa1.

### Operations of Surface-Emitting Laser

The surface-emitting laser 10-6 performs the same operations as the surface-emitting laser 10-1 according to Example 1.

### Method for Manufacturing Surface-Emitting Laser

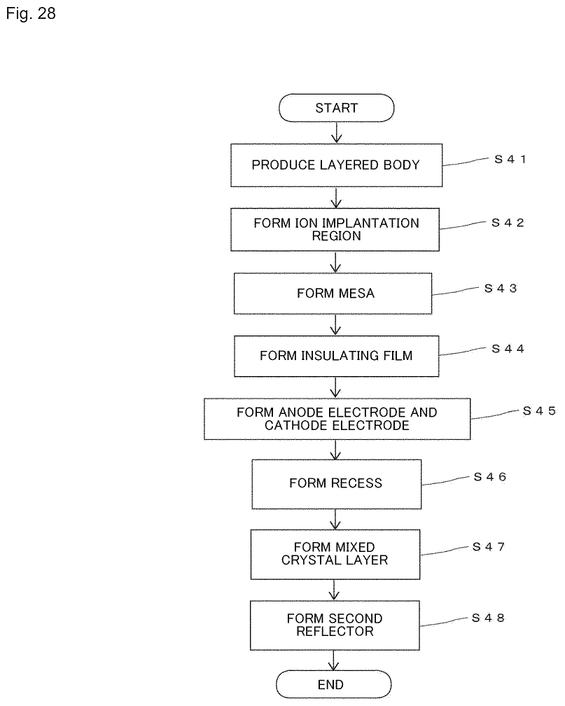

A method for manufacturing the surface-emitting laser 10-6 will be described hereinafter with reference to the flowchart in FIG. 28 and the like. Here, for example, a plurality of surface-emitting lasers 10-6 are produced simultaneously on a single wafer, which serves as the substrate 101, by a semiconductor manufacturing method using a semiconductor manufacturing device. The integrated plurality of surface-emitting lasers 10-6 are then separated to obtain the plurality of surface-emitting lasers 10-6 in chip form (surface-emitting laser chips).

In the first step, step S41, a layered body is produced (see FIG. 4A). Specifically, for example, the first reflector 102, the cladding layer 103, the active layer 104, the cladding layer 105, the tunnel junction layer 106, and the InP layer 107A are layered on the substrate 101 (e.g., the InP substrate) in that order in a growth chamber through metal-organic vapor deposition (MOCVD) or molecular beam epitaxy (MBE), and the layered body is formed.

In the next step, step S42, the ion implantation region IIA is formed. Specifically, a resist pattern RP covering the location where the ion implantation region IIA is not to be formed is first formed on the layered body (see FIG. 4B). Ions (H, He, or the like) are then injected from the first cladding layer 107 side into the layered body using the resist pattern RP as a mask (see FIG. 5A). At this time, the implantation depth of the ions is set such that the ion concentration peaks in the vicinity of the tunnel junction layer 106, for example. After this, the resist pattern RP is removed using an organic solvent or through dry etching using O₂ or CF4 (see FIG. 5B).

In the next step, step S43, the mesa M is formed. Specifically, a hard mask HM constituted by an oxide film (e.g., a SiO₂ film) is first formed so as to cover the location where the mesa M is to be formed on the layered body where the ion implantation region IIA has been formed (see FIG. 6A). At this time, the oxide film is deposited through CVD, sputtering, deposition, or the like, for example. The oxide film is patterned through photolithography and wet etching using a hydrofluoric acid-based etchant. Then, using the hard mask HM as a mask, the layered body is etched through dry etching using, for example, a Cl-based gas (and specifically, a mixed gas such as Cl₂, BCl₃, SiCl₄, Ar, O₂, or the like, for example), and the mesa M is formed (see FIG. 6B). After this, the hard mask HM is removed through wet etching using a hydrofluoric acid-based etchant (see FIG. 7A).

In the next step, step S44, the insulating film 109 is formed. Specifically, the insulating film 109 is first formed on the entire surface of the layered body in which the notch 107b is formed, through CVD, for example (see FIG. 13B). Next, a resist pattern covering the side surfaces of the mesa M is formed through photolithography. Then, using the resist pattern as a mask, the insulating film 109 covering the top part and the peripheral regions of the bottom part of the mesa M (the top surface of the cladding layer 103) is removed through dry etching using, for example, CF4 gas (see FIG. 14A). The resist pattern is then removed through etching.

In the next step, step S45, the anode electrode 110 and the cathode electrode 111 are formed (see FIG. 14B). Specifically, the annular anode electrode 110 is formed in the peripheral part of the top part of the mesa M, and the cathode electrode 111 is formed in the peripheral region of the bottom part of the mesa M, through lift-off, for example.

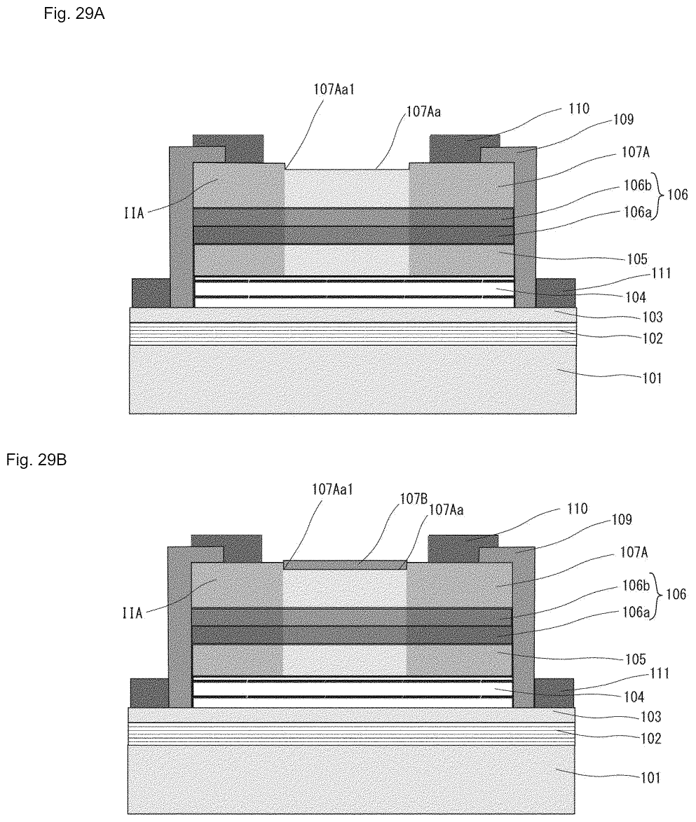

In the next step, step S46, the recess 107Aa is formed (see FIG. 29A). Specifically, a resist pattern covering the locations other than the location of the top part of the mesa M where the recess 107Aa is to be formed is first formed through photolithography. Then, the recess 107Aa is formed through etching (dry etching or wet etching) using the resist pattern as a mask.

In the next step, step S47, the mixed crystal layer 107B is formed (see FIG. 29B). Specifically, the mixed crystal layer 107B is first formed on the entire surface. Then, a resist pattern covering the region corresponding to the light-emitting region of the mixed crystal layer 107B is formed. Then, the mixed crystal layer 107B is formed through etching (dry etching or wet etching) using the resist pattern as a mask.

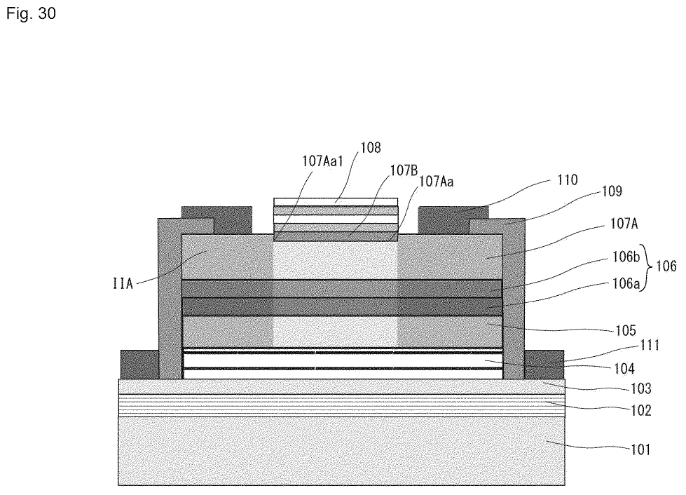

In the final step, step S48, the second reflector 108 is formed (see FIG. 30). Specifically, a dielectric multilayer film is first formed on the entire surface. Next, a resist pattern is formed through photolithography to cover the part where the second reflector 108 is formed. Next, using the resist pattern as a mask, the dielectric multilayer film is etched to form the dielectric multilayer reflector serving as the second reflector 108. The resist pattern is then removed through etching. Note that the second reflector 108 may be formed using lift-off, for example.

### Effects of Surface-Emitting Laser

According to the surface-emitting laser 10-6, the same effects as the surface-emitting laser 10-1 according to Example 1 can be achieved.

### 7. Surface-Emitting Laser According to Example 7 of First Embodiment of Present Technique

A surface-emitting laser according to Example 7 of the first embodiment of the present technique will be described hereinafter.

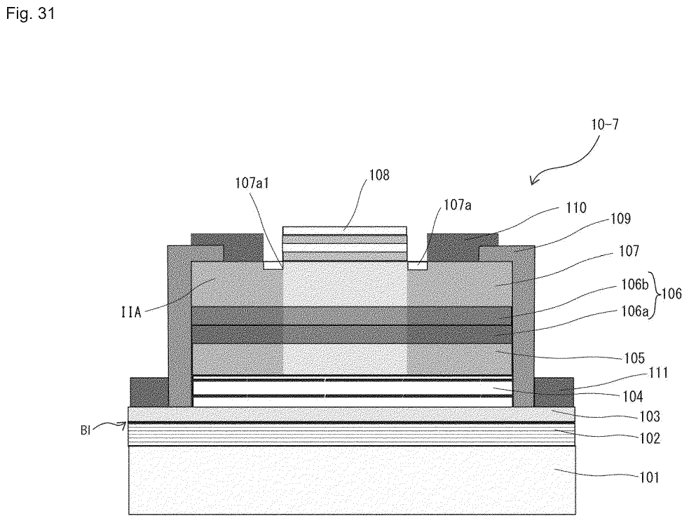

FIG. 31 is a cross-sectional view of a surface-emitting laser 10-7 according to Example 7 of the first embodiment of the present technique.

As illustrated in FIG. 31, the surface-emitting laser 10-7 has the same configuration as the surface-emitting laser 10-1 according to Example 1, except that (i) the first reflector 102 and the cladding layer 103, which is constituted by the same material systems as the semiconductor structure (the cladding layer 105, the tunnel junction layer 106, and the cladding layer 107), are bonded to each other, and (ii) the first reflector 102 and that semiconductor structure are constituted by different material systems.

Here, the substrate 101 is constituted by a GaAs substrate, a Si substrate, or the like, and the first reflector 102 is a semiconductor multilayer reflector constituted by a material that is lattice-matched to GaAs (e.g., AlGaAs/GaAs). The layers constituting the semiconductor structure (the cladding layer 105, the tunnel junction layer 106, and the cladding layer 107) and the cladding layer 103 are constituted by a material lattice-matched to InP or InP. In other words, the first reflector 102 and the semiconductor structure are formed from different material systems. Reference sign BI in FIG. 31 indicates the bonding interface between the first reflector 102 and the cladding layer 103. Note that the GaAs-based cladding layer may be layered on the GaAs-based semiconductor multilayer reflector serving as the first reflector 102, and that cladding layer and the cladding layer 103 (a layer constituted by a material lattice-matched to InP or InP) may be bonded.

### Operations of Surface-Emitting Laser

The surface-emitting laser 10-7 performs the same operations as the surface-emitting laser 10-1 according to Example 1.

### Effects of Surface-Emitting Laser

According to the surface-emitting laser 10-7, the same effects as the surface-emitting laser 10-1 according to Example 1 can be achieved. Furthermore, because a GaAs-based substrate is used as the substrate 101 and a GaAs-based semiconductor multilayer reflector is used as the first reflector 102, the first reflector 102 can achieve high reflectance with a low number of pairs (a thin form), and a mid-wavelength band VCSEL (e.g., a VCSEL having an oscillation wavelength A of less than 900 nm) that can improve heat dissipation performance can be achieved.

### 8. Surface-Emitting Laser According to Example 8 of First Embodiment of Present Technique

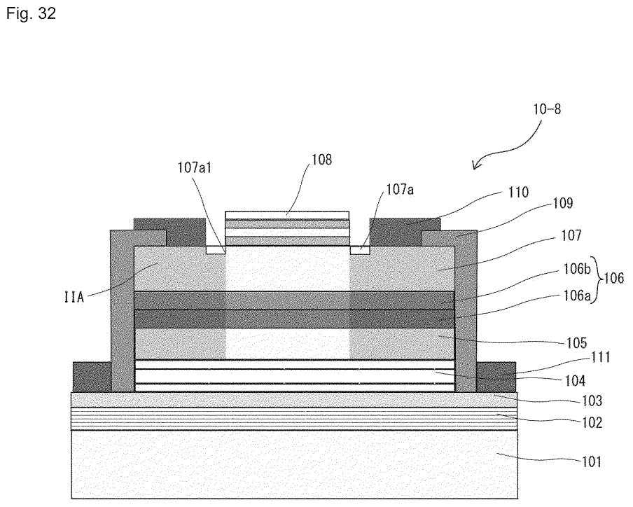

A surface-emitting laser according to Example 8 of the first embodiment of the present technique will be described hereinafter. FIG. 32 is a cross-sectional view of a surface-emitting laser 10-8 according to Example 8 of the first embodiment of the present technique.

As illustrated in FIG. 32, the surface-emitting laser 10-8 according to Example 8 has the same configuration as the surface-emitting laser 10-1 according to Example 1, except that the substrate 101 is constituted by a GaAs substrate, and the first reflector 102, the cladding layer 103, the active layer 104, the cladding layer 105, the tunnel junction layer 106, and the cladding layer 107 are constituted by a material lattice-matched to GaAs or GaAs.

Specifically, the active layer 104 is constituted by InAsQDs, GaInNAs, InGaAs, or the like, for example. The first reflector 102 is constituted by a GaAs-based semiconductor multilayer reflector, for example. The cladding layers 103 and 107 are formed from n-GaAs, and the cladding layer 105 is formed from p-GaAs. The p-type semiconductor region 106a of the tunnel junction layer 106 is constituted by, for example, p-GaAs (with the dopant being C, Mg, Zn, or the like), and the n-type semiconductor region 106b is constituted by, for example, n-GaAs (with the dopant being Si, Te, or the like).

### Operations of Surface-Emitting Laser

The surface-emitting laser 10-8 performs the same operations as the surface-emitting laser 10-1 according to Example 1.

### Effects of Surface-Emitting Laser

According to the surface-emitting laser 10-8, the same effects as the surface-emitting laser 10-1 according to Example 1 can be achieved. Furthermore, the substrate 101 is constituted by a GaAs substrate, and the first reflector 102, the cladding layer 103, the active layer 104, the cladding layer 105, the tunnel junction layer 106, and the cladding layer 107 are constituted by a material lattice-matched to GaAs or GaAs. As such, the first reflector 102 can achieve high reflectance with a low number of pairs (a thin form), the heat dissipation performance can be improved, and a mid-wavelength band VCSEL (e.g., a VCSEL having an oscillation wavelength A of less than 900 nm) that makes it possible to simplify the manufacturing process (skip a bonding process step) can be achieved.

### 9. Surface-Emitting Laser According to Example 9 of First Embodiment of Present Technique

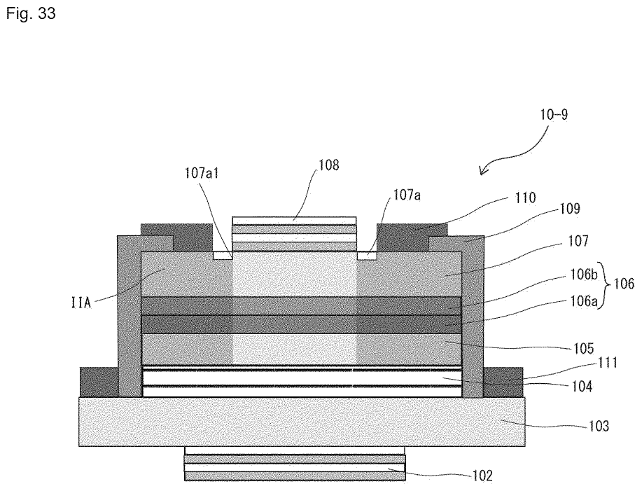

A surface-emitting laser 10-9 according to Example 9 of the first embodiment of the present technique will be described hereinafter. FIG. 33 is a cross-sectional view of a surface-emitting laser 10-9 according to Example 9 of the first embodiment of the present technique.

As illustrated in FIG. 33, the surface-emitting laser 10-9 has the same configuration as the surface-emitting laser 10-1 according to Example 1, except that the substrate 101 is not provided, and a dielectric multilayer reflector serving as the first reflector 102 is provided on the rear surface (the bottom surface) of the cladding layer 103.

### Operations of Surface-Emitting Laser

The surface-emitting laser 10-9 performs the same operations as the surface-emitting laser 10-1 according to Example 1.

### Effects of Surface-Emitting Laser

According to the surface-emitting laser 10-9, the same effects as the surface-emitting laser 10-1 according to Example 1 can be achieved, and because the first reflector 102 constituted by a dielectric multilayer reflector that can achieve high reflectance with a low number of pairs is provided on the rear surface of the cladding layer 103, the laser can be made thinner.

### 10. Surface-Emitting Laser According to Example 10 of First Embodiment of Present Technique

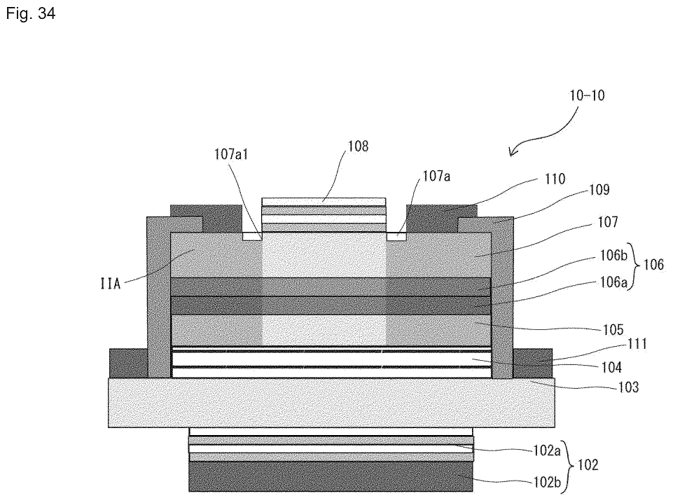

A surface-emitting laser 10-10 according to Example 10 of the first embodiment of the present technique will be described hereinafter. FIG. 34 is a cross-sectional view of the surface-emitting laser 10-10 according to Example 10 of the first embodiment of the present technique.

As illustrated in FIG. 34, the surface-emitting laser 10-10 has the same configuration as the surface-emitting laser 10-9 according to Example 9, except that the first reflector 102 is a hybrid mirror including a dielectric multilayer reflector 102a and a metal film 102b.

In the surface-emitting laser 10-10, the dielectric multilayer reflector 102a is provided on the rear surface (bottom surface) of the cladding layer 103, and the metal film 102b is provided on the rear surface (the bottom surface) of the dielectric multilayer reflector 102a. The aforementioned material can be used as the material of the dielectric multilayer reflector 102a. Au, Ag, Al, Cu, and the like can be given as examples of the material of the metal film 102b.

### Operations of Surface-Emitting Laser

The surface-emitting laser 10-10 performs the same operations as the surface-emitting laser 10-1 according to Example 1.

### Effects of Surface-Emitting Laser

According to the surface-emitting laser 10-10, the same effects as the surface-emitting laser 10-9 according to Example 9 can be achieved. Furthermore, because the first reflector 102 is a hybrid mirror including the dielectric multilayer reflector 102a and the metal film 102b, a high reflectance can be achieved while suppressing an increase in thickness by reducing the number of pairs in the dielectric multilayer reflector 102a, and the heat dissipation performance can furthermore be improved.

### 11. Surface-Emitting Laser According to Example 11 of First Embodiment of Present Technique

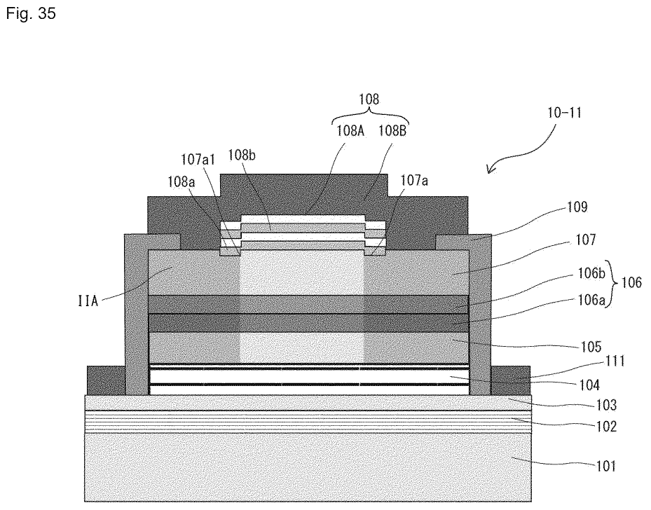

A surface-emitting laser 10-11 according to Example 11 of the first embodiment of the present technique will be described hereinafter. FIG. 35 is a cross-sectional view of the surface-emitting laser 10-11 according to Example 11 of the first embodiment of the present technique.

As illustrated in FIG. 35, the surface-emitting laser 10-11 has the same configuration as the surface-emitting laser 10-4 according to Example 40, except that the second reflector 108 is a hybrid mirror including a dielectric multilayer reflector 108A and a metal film 108B.

In the surface-emitting laser 10-11, the metal film 108B is provided on the dielectric multilayer reflector 108A and the cladding layer 107 in the periphery thereof. The metal film 108B also functions as an anode electrode. The aforementioned material can be used as the material of the dielectric multilayer reflector 108A. Au, Ag, Al, Cu, and the like can be given as examples of the material of the metal film 108B.

In the surface-emitting laser 10-11, the reflectance of the first reflector 102 is set to be slightly lower than the reflectance of the second reflector 108, and the first reflector 102 is a reflector on the emitting side. In other words, the surface-emitting laser 10-11 is a rear surface-emitting type of surface-emitting laser that emits light on the rear surface side (bottom surface side) of the substrate 101.

### Operations of Surface-Emitting Laser

Aside from emitting light from the rear surface side of the substrate 101, the surface-emitting laser 10-11 performs the same operations as the surface-emitting laser 10-1 according to Example 1.

### Effects of Surface-Emitting Laser

According to the surface-emitting laser 10-11, the same effects as the surface-emitting laser 10-1 according to Example 1 can be achieved. Furthermore, because the second reflector 108 is a hybrid mirror including the dielectric multilayer reflector 108A and the metal film 108B, a rear surface-emitting type surface-emitting laser can be realized, which can achieve a high reflectance while suppressing an increase in thickness by reducing the number of pairs in the dielectric multilayer reflector 108A, and which furthermore can improve the heat dissipation performance. In addition, according to the surface-emitting laser 10-11, the metal film 108B of the second reflector 108 also serves as the anode electrode, and thus a part of the hybrid mirror and a heat dissipation part can be substantially formed by forming the electrode.

### 12. Surface-Emitting Laser According to Example 12 of First Embodiment of Present Technique

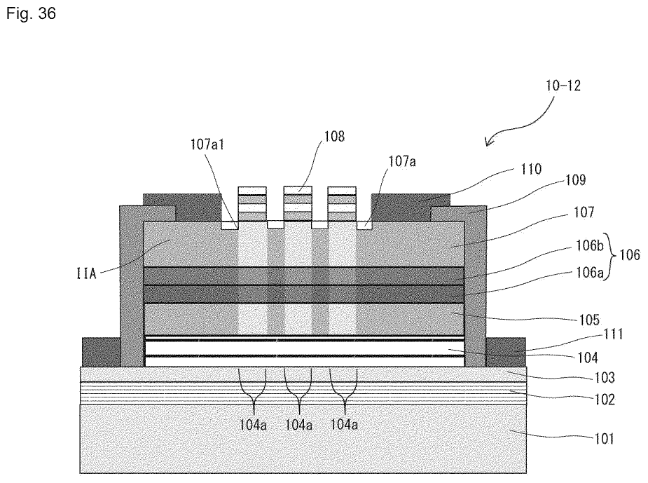

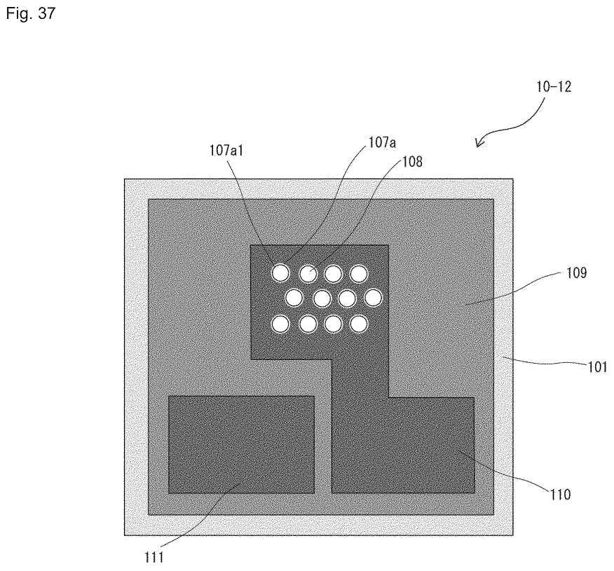

A surface-emitting laser 10-12 according to Example 12 of the first embodiment of the present technique will be described hereinafter. FIG. 36 is a cross-sectional view of the surface-emitting laser 10-12 according to Example 12 of the first embodiment of the present technique. FIG. 37 is a plan view of the surface-emitting laser 10-12 according to Example 12 of the first embodiment of the present technique.

As illustrated in FIG. 36, the surface-emitting laser 10-12 has the same configuration as the surface-emitting laser 10-1 according to Example 1, except that the ion implantation region IIA serving as the current confinement region has a plurality of annular light-emitting region setting parts.

In the surface-emitting laser 10-12, a plurality of light-emitting regions 104a are set in the active layer 104 by the plurality of light-emitting region setting parts of the ion implantation region IIA. In other words, the surface-emitting laser 10-12 forms a surface-emitting laser array in which a plurality of resonators each including the light-emitting region 104a are arranged in an array.

Here, a plurality of the annular step parts 107a1 corresponding to the plurality of light-emitting regions 104a are provided on the surface of the cladding layer 107 on the second reflector 108 side thereof (see FIG. 37).

### Operations of Surface-Emitting Laser

Aside from laser oscillation being performed by each resonator including the light-emitting region 104a, the surface-emitting laser 10-12 performs the same operations as the surface-emitting laser 10-1 according to Example 1.

### Effects of Surface-Emitting Laser

According to the surface-emitting laser 10-12, the same effects as the surface-emitting laser 10-1 according to Example 1 can be achieved, and a surface-emitting laser array that can increase the output and improve the efficiency of each resonator can be achieved.

### 13. Light Source Device Including Surface-Emitting Laser According to Example 12 of First Embodiment of Present Technique, and Ranging Device Including Light Source Device

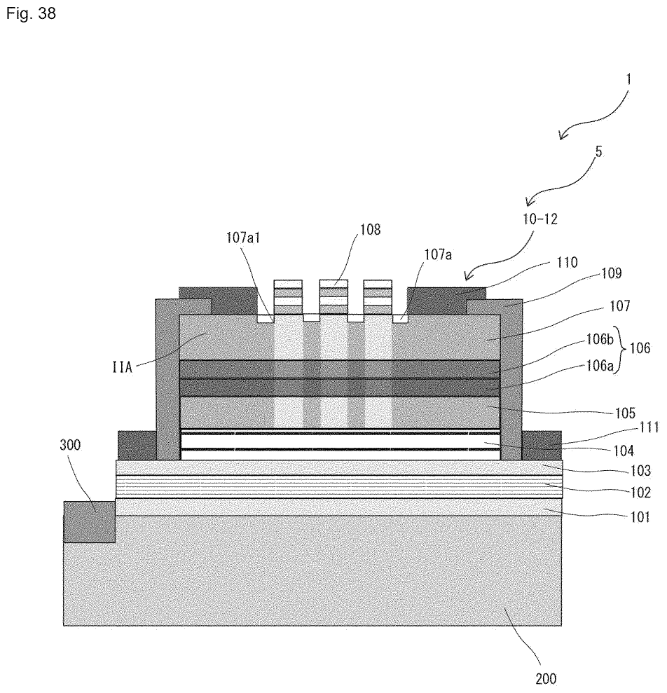

A light source device including the surface-emitting laser according to Example 12 of first embodiment of present technique, and a ranging device including the light source device, will be described hereinafter. FIG. 38 is a cross-sectional view of a ranging device 1 provided with a light source device 5 including the surface-emitting laser 10-12 according to Example 12 of the first embodiment of the present technique.

As illustrated in FIG. 38, the light source device 5 includes the surface-emitting laser 10-12, and a circuit board 200 bonded to the surface of the surface-emitting laser 10-12 on the first reflector 102 side thereof. The circuit board 200 is a Si substrate on which driver circuitry (a laser driver) for driving the resonator of each surface-emitting laser 10-12 is formed. Control circuitry and computation circuitry for Time Of Flight (TOF) are also formed on the Si substrate.

The ranging device 1 provided with the light source device 5 includes the light source device 5, and a light-receiving element 300 mounted on the Si substrate serving as the circuit board 200 of the light source device 5. The light-receiving element 300 includes an avalanche photodiode (APD) constituted by, for example, SiGe, and is sensitive to long wavelengths. The ranging device 1 constitutes a TOF module employing silicon photonics, including the light source device 5 and the light-receiving element 300 provided on the Si substrate.

### Operations of Ranging Device

In the ranging device 1, a light emission signal is applied to the driver circuitry from the control circuitry of the circuit board 200, and a driving voltage is applied to the surface-emitting laser 10-12 from the driver circuitry. At this time, the plurality of resonators of the surface-emitting lasers 10-12 perform laser oscillation, and a plurality of laser beams are emitted as emitted light. The plurality of laser beams emitted onto an object are reflected back by the object and are received by the light-receiving element 300. At this time, a light reception signal is transmitted from the light-receiving element 300 to the computation circuitry, and the computation circuitry performs predetermined computations based on at least on the light reception signal, calculates a distance to the object for each resonator, and generates a range image.

### Effects of Ranging Device

According to the ranging device 1, ranging is performed using the surface-emitting laser 10-12, which is a high-output and highly efficient long-wavelength band surface-emitting laser array, and the light-receiving element 300, which is sensitive to long wavelengths, and it is therefore possible to measure the distance to an object and the shape of the object with high accuracy while helping to ensure eye safety.

### 14. Surface-Emitting Laser According to Variation on Example 1 of First Embodiment of Present Technique

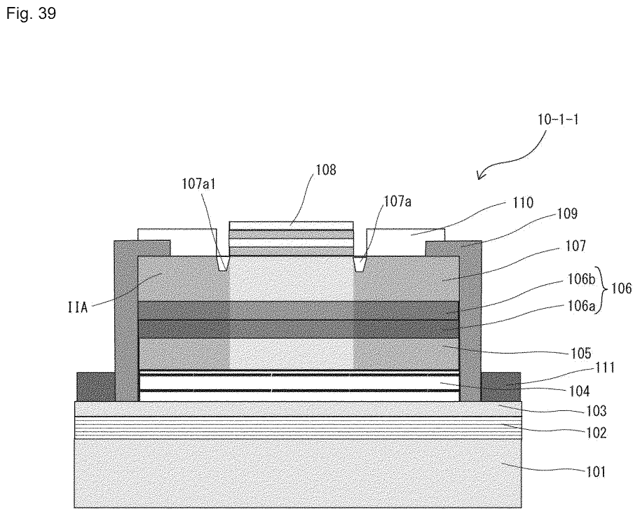

A surface-emitting laser 10-1-1 according to a variation on Example 1 of the first embodiment of the present technique will be described hereinafter. FIG. 39 is a cross-sectional view of the surface-emitting laser 10-1-1 according to a variation on Example 1 of the first embodiment of the present technique.

The surface-emitting laser 10-1-1 has the same configuration as the surface-emitting laser 10-1 according to Example 1, except that the vertical cross-sections of the annular groove 107a and the annular step part 107a1 have a tapered shape. More specifically, the base surface and the side surface of the annular step part 107a1 form an obtuse angle.

### Operations of Surface-Emitting Laser

The surface-emitting laser 10-1-1 performs the same operations as the surface-emitting laser 10-1 according to Example 1.

### Effects of Surface-Emitting Laser

According to the surface-emitting laser 10-1-1, a light confinement effect can be achieved, even when the vertical cross-section of the annular step part 107a1 is a tapered shape.

Note, however, that the vertical cross-section of the annular step part 107a1 may be an inverted tapered shape (a shape in which the base surface and the side surface form an acute angle). A light confinement effect can be achieved in this case as well.

### 15. Surface-Emitting Laser According to Variation on Example 4 of First Embodiment of Present Technique

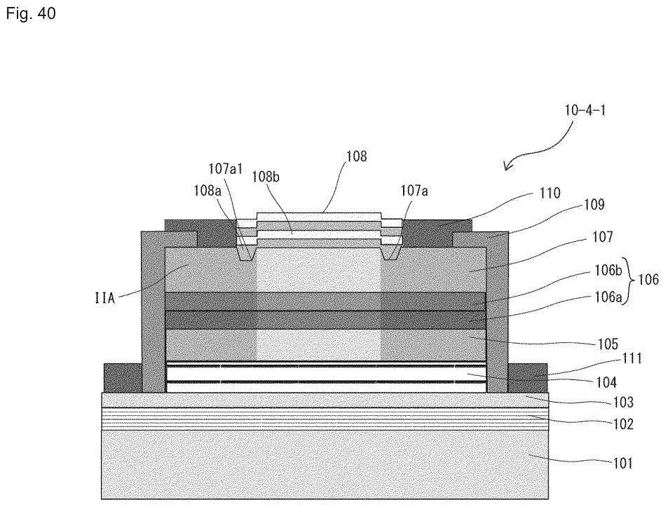

A surface-emitting laser 10-4-1 according to a variation on Example 4 of the first embodiment of the present technique will be described hereinafter. FIG. 40 is a cross-sectional view of the surface-emitting laser 10-4-1 according to a variation on Example 4 of the first embodiment of the present technique.

The surface-emitting laser 10-4-1 has the same configuration as the surface-emitting laser 10-4 according to Example 4, except that the vertical cross-sections of the annular groove 107a and the annular step part 107a1 have a tapered shape.

### Operations of Surface-Emitting Laser

The surface-emitting laser 10-4-1 performs the same operations as the surface-emitting laser 10-1 according to Example 1.

### Effects of Surface-Emitting Laser

According to the surface-emitting laser 10-4-1, a light confinement effect can be achieved, even when the vertical cross-section of the annular step part 107a1 is a tapered shape. In addition, in the surface-emitting laser 10-4-1, the vertical cross-section of the annular step part 107a1 being a tapered shape provides an advantage in that the low refractive index layer 108a can be formed with ease on the annular step part 107a1 during manufacture.

Note, however, that the vertical cross-section of the annular step part 107a1 may be an inverted tapered shape. A light confinement effect can be achieved in this case as well.

### 16. Surface-Emitting Laser According to Variation on Example 5 of First Embodiment of Present Technique

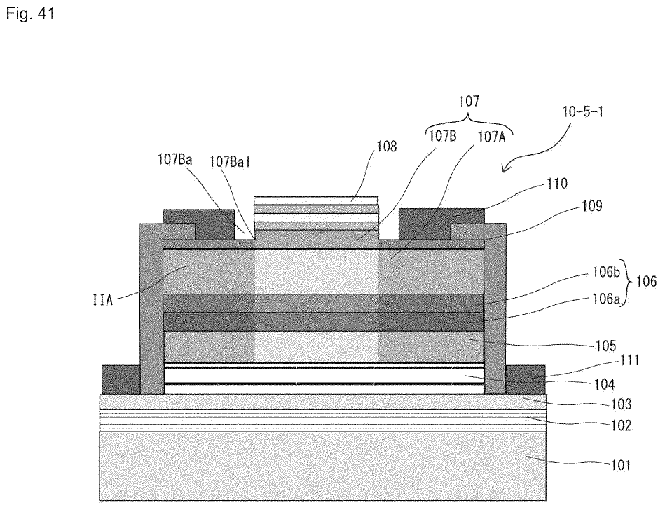

A surface-emitting laser 10-5-1 according to a variation on Example 5 of the first embodiment of the present technique will be described hereinafter. FIG. 41 is a cross-sectional view of the surface-emitting laser 10-5-1 according to a variation on Example 5 of the first embodiment of the present technique.

The surface-emitting laser 10-5-1 has the same configuration as the surface-emitting laser 10-5 according to Example 5, except that the surface layer of the cladding layer 107 on the second reflector 108 side is constituted by a material lattice-matched with InP.

In the surface-emitting laser 10-5-1, for example, in the surface layer of the cladding layer 107 on the second reflector 108 side, a peripheral part corresponding to the light-emitting region setting part of the ion implantation region IIA, and a central part surrounded by the light-emitting region setting part of the ion implantation region IIA, are constituted by the mixed crystal layer 107B formed from a material lattice-matched to InP (e.g., mixed crystals such as InGaAsP, AlGaInAs, or the like). In particular, using InGaAsP for the material of the mixed crystal layer 107B enables the layer to also function as an etching stop layer. Here, the cladding layer 107 has a two-layer structure in which the mixed crystal layer 107B is layered on the InP layer 107A. An annular notch 107Ba is provided in the mixed crystal layer 107B so as to surround a central region corresponding to the light-emitting region. A step part of the notch 107Ba corresponds to an annular step part 107Ba1.

### Operations of Surface-Emitting Laser

The surface-emitting laser 10-5-1 performs the same operations as the surface-emitting laser 10-1 according to Example 1.

### Effects of Surface-Emitting Laser

According to the surface-emitting laser 10-5-1, the same effects as the surface-emitting laser 10-5 according to Example 5 can be achieved.

### 17. Surface-Emitting Laser According to Variation on Example 12 of First Embodiment of Present Technique

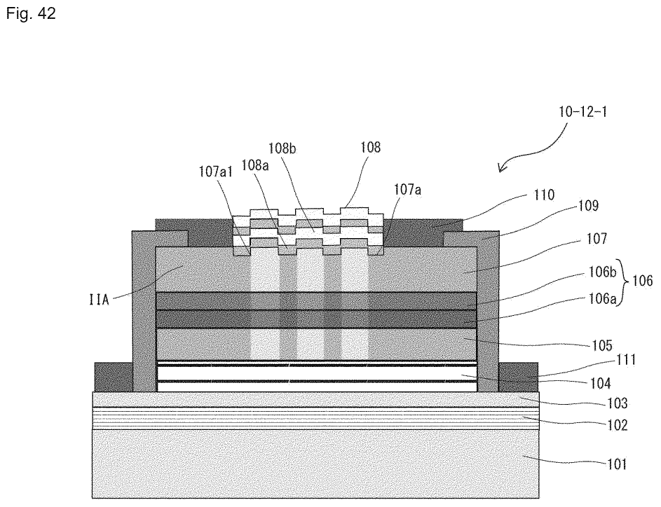

A surface-emitting laser 10-12-1 according to a variation on Example 12 of the first embodiment of the present technique will be described hereinafter. FIG. 42 is a cross-sectional view of the surface-emitting laser 10-12-1 according to a variation on Example 12 of the first embodiment of the present technique.

The surface-emitting laser 10-12-1 has the same configuration as the surface-emitting laser 10-12-1 according to Example 12, except that the low refractive index layer 108a is provided in contact with each annular step part 107a1.

In the surface-emitting laser 10-12-1, the low refractive index layer 108a enters into each annular groove 107a.

### Operations of Surface-Emitting Laser

The surface-emitting laser 10-12-1 performs the same operations as the surface-emitting laser 10-12 according to Example 12.

### Effects of Surface-Emitting Laser

According to the surface-emitting laser 10-12-1, the same effects as the surface-emitting laser 10-12 according to Example 12 can be achieved.

### 18. Surface-Emitting Laser According to Example 1 of Second Embodiment of Present Technique

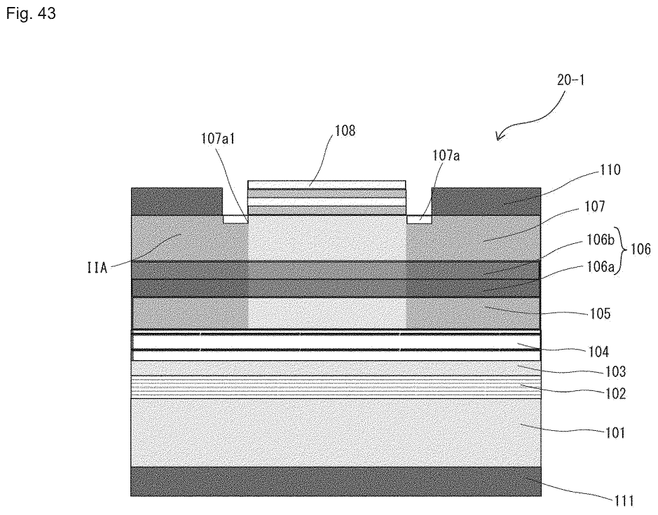

A surface-emitting laser 20-1 according to Example 1 of a second embodiment of the present technique will be described hereinafter. FIG. 43 is a cross-sectional view of the surface-emitting laser 20-1 according to Example 1 of the second embodiment of the present technique.

The surface-emitting laser 20-1 has generally the same configuration as the surface-emitting laser 10-1 according to Example 1, except that the mesa M is not formed.

In the surface-emitting laser 20-1, the cathode electrode 111 is provided in a solid shape on the rear surface (the bottom surface) of the substrate 101.

### Operations of Surface-Emitting Laser

The surface-emitting laser 20-1 performs the same operations as the surface-emitting laser 10-1 according to Example 1, except that the current path from the anode electrode 110 to the cathode electrode 111 crosses the first reflector 102 and the substrate 101.

### Effects of Surface-Emitting Laser

According to the surface-emitting laser 20-1, the same effects as the surface-emitting laser 10-1 according to Example 1 can be achieved.

### 19. Surface-Emitting Laser According to Example 2 of Second Embodiment of Present Technique

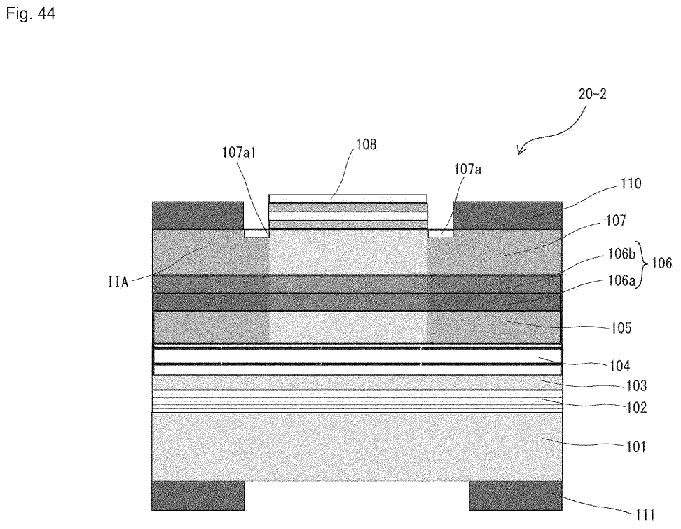

A surface-emitting laser 20-2 according to Example 2 of the second embodiment of the present technique will be described hereinafter. FIG. 44 is a cross-sectional view of the surface-emitting laser 20-2 according to Example 2 of the second embodiment of the present technique.

The surface-emitting laser 20-2 has generally the same configuration as the surface-emitting laser 20-1 according to Example 1, except that the cathode electrode 111 is provided on the rear surface of the substrate 101 in an annular shape so as to surround the light-emitting region in plan view.

With the surface-emitting laser 20-2, the magnitudes of the reflectances of the first and second reflectors 102 and 108 make it possible to configure either a front surface-emitting type or rear surface-emitting type surface-emitting laser.

### Operations of Surface-Emitting Laser

The surface-emitting laser 20-2 performs the same operations as the surface-emitting laser 20-1 according to Example 1.

### Effects of Surface-Emitting Laser

According to the surface-emitting laser 20-2, the same effects as the surface-emitting laser 20-1 according to Example 1 can be achieved, and the emission type can furthermore be selected.

### 20. Surface-Emitting Laser According to Example 3 of Second Embodiment of Present Technique

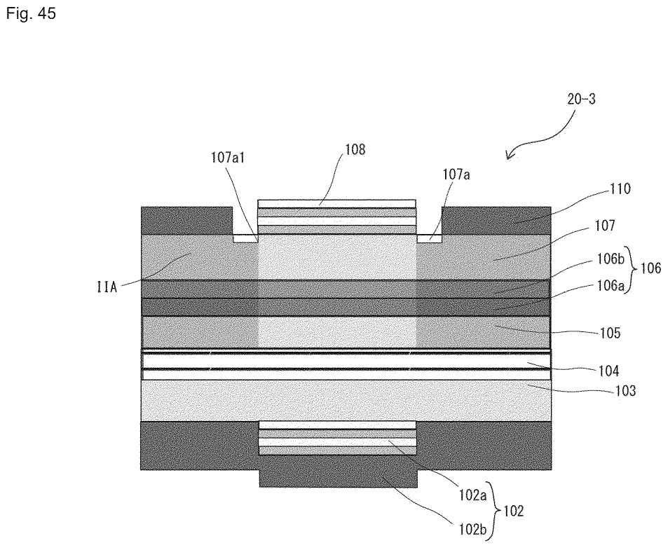

A surface-emitting laser 20-3 according to Example 3 of the second embodiment of the present technique will be described hereinafter. FIG. 45 is a cross-sectional view of the surface-emitting laser 20-3 according to Example 3 of the second embodiment of the present technique.

The surface-emitting laser 20-3 has the same configuration as the surface-emitting laser 20-1 according to Example 1, except that the first reflector 102 is a hybrid mirror including the dielectric multilayer reflector 102a and the metal film 102b.

In the surface-emitting laser 20-3, the metal film 102b is provided on the rear surface (bottom surface) of the dielectric multilayer reflector 102a and the rear surface (bottom surface) of the cladding layer 103 in the periphery thereof. The metal film 102b also functions as a cathode electrode. The aforementioned dielectric material can be used as the material of the dielectric multilayer reflector 102a. Au, Ag, Al, Cu, and the like can be given as examples of the material of the metal film 102b.

### Operations of Surface-Emitting Laser

The surface-emitting laser 20-3 performs the same operations as the surface-emitting laser 20-1 according to Example 1.

### Effects of Surface-Emitting Laser

According to the surface-emitting laser 20-3, the same effects as the surface-emitting laser 20-1 according to Example 1 can be achieved. Furthermore, because the first reflector 102 is a hybrid mirror including the dielectric multilayer reflector 102a and the metal film 102b, a front surface-emitting type surface-emitting laser can be realized, which can achieve a high reflectance while suppressing an increase in thickness by reducing the number of pairs in the dielectric multilayer reflector 102a, and which furthermore can improve the heat dissipation performance. In addition, according to the surface-emitting laser 20-3, the metal film 102b of the first reflector 102 also serves as the cathode electrode, and thus a part of the hybrid mirror and a heat dissipation part can be substantially formed by forming the electrode.

### 21. Surface-Emitting Laser According to Example 4 of Second Embodiment of Present Technique

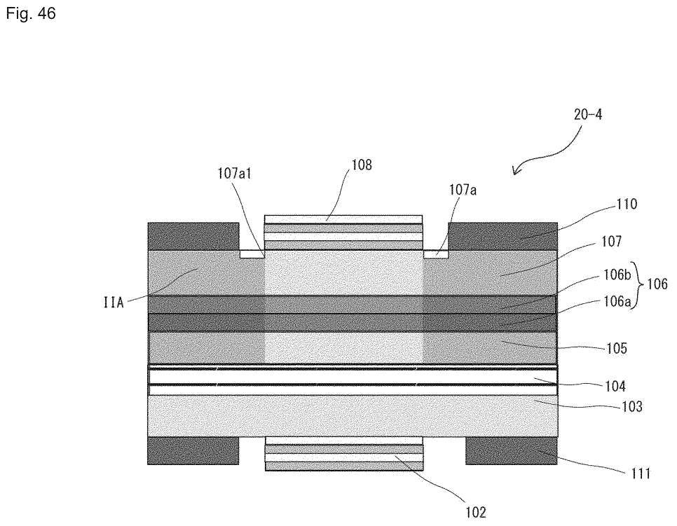

A surface-emitting laser 20-4 according to Example 4 of the second embodiment of the present technique will be described hereinafter. FIG. 46 is a cross-sectional view of the surface-emitting laser 20-4 according to Example 4 of the second embodiment of the present technique.

The surface-emitting laser 20-4 has generally the same configuration as the surface-emitting laser 20-3 according to Example 3, except that the first reflector 102 is a dielectric multilayer reflector, and the cathode electrode 111 is provided on the rear surface of the substrate 101 in an annular shape so as to surround the first reflector 102.

With the surface-emitting laser 20-4, the magnitudes of the reflectances of the first and second reflectors 102 and 108 make it possible to configure either a front surface-emitting type or rear surface-emitting type surface-emitting laser.

### Operations of Surface-Emitting Laser

The surface-emitting laser 20-4 performs the same operations as the surface-emitting laser 20-1 according to Example 1.

### Effects of Surface-Emitting Laser

According to the surface-emitting laser 20-4, the same effects as the surface-emitting laser 20-1 according to Example 1 can be achieved, and the emission type can furthermore be selected.

### 22. Other Variations on Present Technique

The present technique is not limited to the foregoing examples and variations, and can be varied in other ways as well.

For example, in plan view, the annular step part may extend around the outside (e.g., approximately several nm to 2 μm outside) of the inner peripheral edge of the light-emitting region setting part.

For example, in each of the foregoing examples and variations, the conductivity types (p-type and n-type) may be swapped with respect to the vertical direction.

The plan view shape of the annular step part may be an annular shape other than a circle, such as an ellipse, for example.

Some of the configurations of the surface-emitting lasers in the foregoing examples and variations may be combined as long as they do not conflict with each other.

In each of the examples and variations described above, the material, conductivity type, thickness, width, length, shape, size, arrangement, and the like of each component constituting the surface-emitting laser can be changed as needed within a scope in which the function as a surface-emitting laser is maintained.

### 23. Example of Application to Electronic Device

The technique according to the present disclosure (the present technique) can be applied in various products (electronic devices). For example, the technique according to the present disclosure may be realized as a device mounted on any type of moving body such as an automobile, an electric automobile, a hybrid electric automobile, a motorcycle, a bicycle, a personal mobility device, an airplane, a drone, a ship, a robot, or the like.

The surface-emitting laser according to the present technique can be applied, for example, as a light source for a device that forms or displays images using laser light (e.g., laser printers, laser copiers, projectors, head-mounted displays, heads-up displays, and the like).

### 24. Example of Applying Surface-Emitting Laser to Distance Measurement Device

An example of the application of the surface-emitting laser according to the foregoing examples will be described hereinafter.

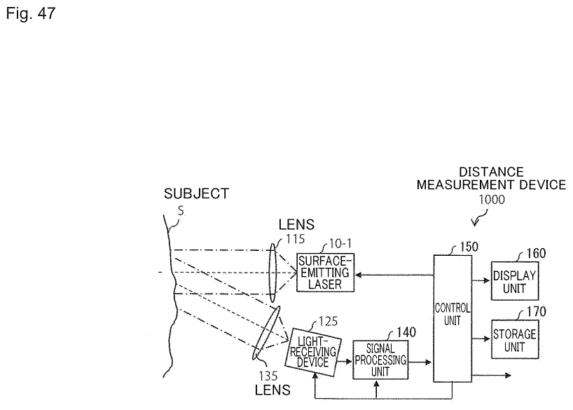

FIG. 47 illustrates an example of the overall configuration of a distance measurement device 1000 including the surface-emitting laser 10-1 as an example of an electronic device. The distance measurement device 1000 measures the distance to a subject S using the Time Of Flight (TOF) method. The distance measurement device 1000 includes the surface-emitting laser 10-1 as a light source. The distance measurement device 1000 includes, for example, the surface-emitting laser 10-1, a light-receiving device 125, lenses 115 and 135, a signal processing unit 140, a control unit 150, a display unit 160, and a storage unit 170.

The light receiving device 125 detects light reflected by the subject S. The lens 115 is a lens for converting light emitted from the surface-emitting laser 10-1 into parallel light, and is a collimate lens. The lens 135 is a lens for focusing light reflected by the subject S and guiding that light to the light-receiving device 125, and is a focusing lens.

The signal processing unit 140 is a circuit for generating a signal corresponding to a difference between a signal input from the light-receiving device 125 and a reference signal input from the control unit 150. The control unit 150 is configured including a Time to Digital Converter (TDC), for example. The reference signal may be a signal input from the control unit 150, or may be an output signal from a detection unit that directly detects the output of the surface-emitting laser 10-1. The control unit 150 is, for example, a processor that controls the surface-emitting laser 10-1, the light-receiving device 125, the signal processing unit 140, the display unit 160, and the storage unit 170. The control unit 150 is a circuit that measures the distance to the subject S based on the signal generated by the signal processing unit 140. The control unit 150 generates an image signal for displaying information about the distance to the subject S, and outputs the image signal to the display unit 160. The display unit 160 displays the information about the distance to the subject S based on the image signal input from the control unit 150. The control unit 150 stores the information about the distance to the subject S in the storage unit 170.

In the present application example, any of the foregoing surface-emitting lasers 10-1 to 10-12, 10-1-1, 10-4-1, 10-5-1, 10-12-1, and 20-1 to 20-4 can be applied in the distance measurement device 1000 instead of the surface-emitting laser 10-1.

### 25. Example of Installing Distance Measurement Device on Moving Body

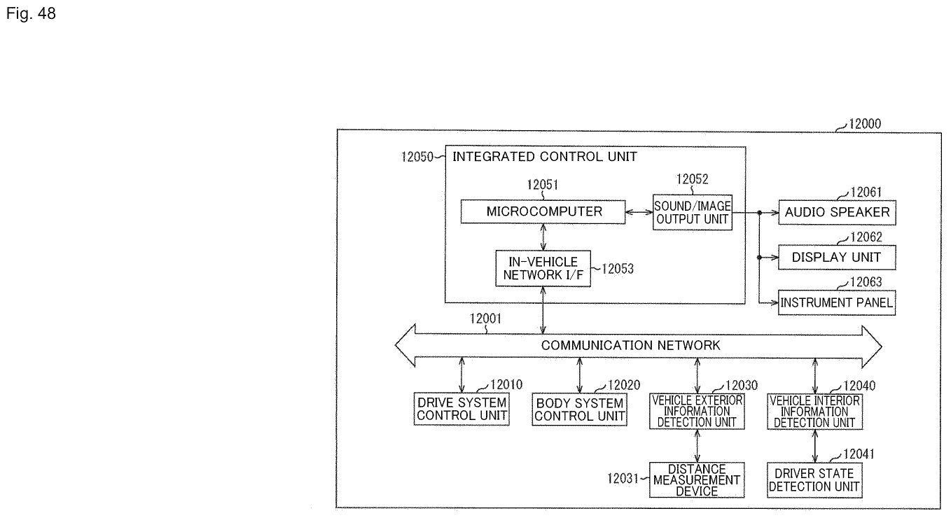

FIG. 48 is a block diagram schematically illustrating an example of the configuration of a vehicle control system, which is an example of a moving body control system to which the technique according to the present disclosure can be applied.

A vehicle control system 12000 includes a plurality of electronic control units connected over a communication network 12001. In the example illustrated in FIG. 48, the vehicle control system 12000 includes a drive system control unit 12010, a body system control unit 12020, a vehicle exterior information detection unit 12030, a vehicle interior information detection unit 12040, and an integrated control unit 12050. In addition, a microcomputer 12051, a sound/image output unit 12052, and an in-vehicle network interface (I/F) 12053 are illustrated as functional configurations of the integrated control unit 12050.

The drive system control unit 12010 controls operations of devices related to a drive system of the vehicle according to various types of programs. For example, the drive system control unit 12010 functions as control devices, such as a driving force generation device for generating driving force for the vehicle, such as an internal combustion engine or a driving motor; a driving force transmission mechanism for transmitting driving force to wheels; a steering mechanism for adjusting a turning angle of the vehicle; a braking device that generates braking force for the vehicle; and the like.

The body system control unit 12020 controls operations of various devices mounted in the vehicle body according to various programs. For example, the body system control unit 12020 functions as control devices for a keyless entry system, a smart key system, power window devices, or various lamps such as headlights, backup lights, brake lights, turn signals, fog lights, and the like. In this case, radio waves emitted from a portable device that substitutes for a key or signals from various switches can be input to the body system control unit 12020. The body system control unit 12020 receives the input of the radio waves or signals and controls door lock devices, power window devices, the lamps, and the like of the vehicle.

The vehicle exterior information detection unit 12030 detects information on the exterior of the vehicle in which the vehicle control system 12000 is installed. For example, a distance measurement device 12031 is connected to the vehicle exterior information detection unit 12030. The distance measurement device 12031 includes the distance measurement device 1000 described above. The vehicle exterior information detection unit 12030 causes the distance measurement device 12031 to measure the distance to an object (the subject S) outside of the vehicle and obtains distance data obtained as a result. The vehicle exterior information detection unit 12030 may perform object detection processing for people, cars, obstacles, signs, and the like based on the obtained distance data.

The vehicle interior information detection unit 12040 detects information on the interior of the vehicle. For example, a driver state detection unit 12041 that detects a state of a driver is connected to the vehicle interior information detection unit 12040. The driver state detection unit 12041 includes, for example, a camera that captures an image of the driver, and the vehicle interior information detection unit 12040 may calculate the level of the driver's fatigue or concentration, or may determine whether the driver is dozing, based on detection information input from the driver state detection unit 12041.

For example, the microcomputer 12051 can calculate control target values for the driving force generation device, the steering mechanism, or the braking device based on information on the inside and outside of the vehicle obtained by the vehicle exterior information detection unit 12030 and the vehicle interior information detection unit 12040, and output control commands to the drive system control unit 12010. For example, the microcomputer 12051 can perform coordinated control for the purpose of implementing functions of an Advanced Driver Assistance System (ADAS) including vehicle collision avoidance, impact mitigation, following traveling based on an inter-vehicle distance, constant vehicle speed driving, vehicle collision warnings, and lane departure warnings.

In addition, the microcomputer 12051 can perform coordinated control for the purpose of automated driving or the like in which autonomous travel is performed without requiring operations of the driver, by controlling the driving force generation device, the steering mechanism, the braking device, or the like based on information about the surroundings of the vehicle, the information being obtained by the vehicle exterior information detection unit 12030 or the vehicle interior information detection unit 12040.

In addition, the microcomputer 12051 can output control commands to the body system control unit 12020 based on the information on the exterior of the vehicle obtained by the vehicle exterior information detection unit 12030. For example, the microcomputer 12051 can perform coordinated control for the purpose of suppressing glare, such as switching from high beams to low beams by controlling the headlights according to the position of a preceding vehicle or an oncoming vehicle detected by the vehicle exterior information detection unit 12030.

The sound/image output unit 12052 transmits an output signal of at least one of sound and an image to an output device capable of visually or audibly providing information to an occupant or to the exterior of the vehicle. In the example illustrated in FIG. 48, an audio speaker 12061, a display unit 12062, and an instrument panel 12063 are illustrated as examples of the output device. The display unit 12062 may include at least one of an on-board display and a heads-up display, for example.

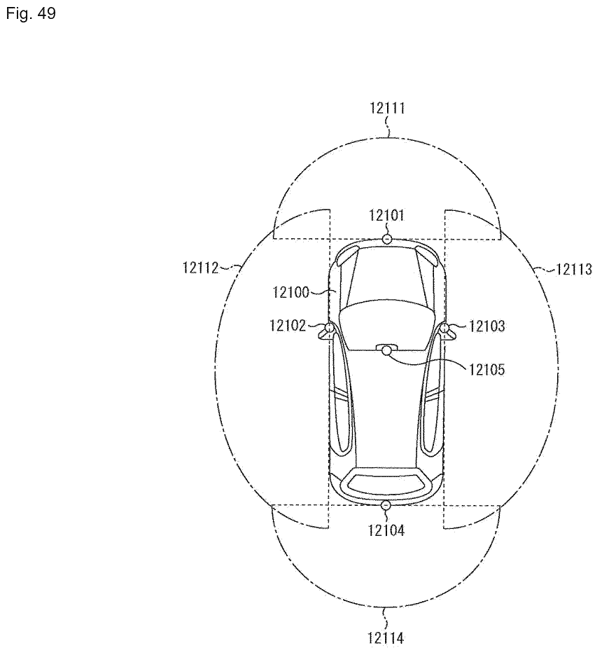

FIG. 49 is a diagram illustrating an example of an installation positions of the distance measurement device 12031.

In FIG. 49, a vehicle 12100 has distance measurement devices 12101, 12102, 12103, 12104, and 12105 as the distance measurement device 12031.

The distance measurement devices 12101, 12102, 12103, 12104, and 12105 are provided at the positions of the front nose, the side-view mirrors, the rear bumper, the trunk door, an upper part of the windshield within the vehicle cabin, and the like of a vehicle 12100, for example. The distance measurement device 12101 provided on the front nose and the distance measurement device 12105 provided in an upper part of the windshield within the vehicle cabin mainly obtain data from in front of the vehicle 12100. The distance measurement devices 12102 and 12103 provided in the side-view mirrors mainly obtain data from the sides of the vehicle 12100. The distance measurement device 12104 provided on the rear bumper or the trunk door mainly obtains data of an area behind the vehicle 12100. The data obtained by the distance measurement devices 12101 and 12105 is mainly used for detecting preceding vehicles, pedestrians, obstacles, traffic signals, traffic signs, and the like.

FIG. 49 illustrates an example of detection ranges of the distance measurement devices 12101 to 12104. A detection range 12111 indicates a detection range of the distance measurement device 12101 provided on the front nose; detection ranges 12112 and 12113 respectively indicate the detection ranges of the distance measurement devices 12102 and 12103 provided in the side-view mirrors; and a detection range 12114 indicates the detection range of the distance measurement device 12104 provided on the rear bumper or the trunk door.

For example, the microcomputer 12051 can extract, particularly, a closest three-dimensional object on a path through which the vehicle 12100 is traveling, which is a three-dimensional object traveling at a predetermined speed (for example, at least 0 km/h) in substantially the same direction as the vehicle 12100, as a preceding vehicle by obtaining a distance to each three-dimensional object in the detection ranges 12111 to 12114 and temporal changes in the distance (a relative speed with respect to the vehicle 12100) based on the distance data obtained from the distance measurement devices 12101 to 12104. The microcomputer 12051 can also set an inter-vehicle distance to the preceding vehicle to be maintained in advance and perform automatic brake control (including following stop control) and automatic acceleration control (including following start control). It is therefore possible to perform coordinated control for the purpose of, for example, automated driving in which the vehicle travels in an automated manner without requiring the driver to perform operations.

For example, the microcomputer 12051 can classify and extract three-dimensional data regarding three-dimensional objects as two-wheeled vehicles, normal vehicles, large vehicles, pedestrians, and other three-dimensional objects such as electrical poles based on the distance data obtained from the distance measurement devices 12101 to 12104, and can use the three-dimensional data to automatically avoid obstacles. For example, the microcomputer 12051 classifies obstacles around the vehicle 12100 into obstacles visible to the driver of the vehicle 12100 and obstacles which are difficult to see. Then, the microcomputer 12051 determines a collision risk indicating the degree of risk of collision with each obstacle, and when the collision risk is at least a set value and there is a possibility of a collision, an alarm is output to the driver through the audio speaker 12061 or the display unit 12062, forced deceleration or avoidance steering is performed through the drive system control unit 12010, and the like, making it possible to provide driving assistance for collision avoidance.

An example of the moving body control system to which the technique according to the present disclosure can be applied has been described thus far. The technique according to the present disclosure may be applied in the distance measurement device 12031 and the like among the above-described configurations.

In addition, the present technique can also have the following configurations.

(1) A surface-emitting laser including:
first and second reflectors;
an active layer disposed between the first and second reflectors; and
a semiconductor structure disposed between the active layer and the second reflector,
wherein an annular step part is provided on a surface of the semiconductor structure on a side where the second reflector is located.

(2) The surface-emitting laser according to (1),
wherein the semiconductor structure is provided with a current confinement region having at least one annular light-emitting region setting part that sets a light-emitting region of the active layer, and
in plan view, the annular step part surrounds a center of the light-emitting region.

(3) The surface-emitting laser according to (2),
wherein in plan view, the annular step part extends along an inner peripheral edge of the light-emitting region setting part.

(4) The surface-emitting laser according to (3),
wherein in plan view, the annular step part extends along an inner side of the inner peripheral edge.

(5) The surface-emitting laser according to (3),
wherein in plan view, the annular step part extends along the inner peripheral edge while overlapping with the inner peripheral edge.

(6) The surface-emitting laser according to any one of (1) to (5),
wherein the semiconductor structure includes a cladding layer, one surface of which is the surface.

(7) The surface-emitting laser according to (6),
wherein a base surface of the annular step part is located within the cladding layer.

(8) The surface-emitting laser according to (6) or (7),
wherein a surface layer including the one surface of the cladding layer is constituted by a material lattice-matched to InP and/or InP.

(9) The surface-emitting laser according to (8),
wherein the material is a mixed crystal.

(10) The surface-emitting laser according to any one of (6) to (9),
wherein an annular low refractive index layer having a lower refractive index than the cladding layer is provided in contact with the annular step part.

(11) The surface-emitting laser according to (10),
wherein the low refractive index layer is constituted by a dielectric.

(12) The surface-emitting laser according to (10) or (11),
wherein the second reflector is a dielectric multilayer reflector, and
the low refractive index layer is one of a pair in the dielectric multilayer reflector.

(13) The surface-emitting laser according to any one of (10) to (12),
wherein the low refractive index layer is constituted by SiO₂ or Al₂O₃.

(14) The surface-emitting laser according to any one of (6) to (13),
wherein the semiconductor structure includes:
another cladding layer disposed between the cladding layer and the active layer; and
a tunnel junction layer disposed between the cladding layer and the other cladding layer.

(15) The surface-emitting laser according to any one of (1) to (14), further including:
a cladding layer that is disposed between the first reflector and the active layer and is formed from a material system of the same type as the semiconductor structure,
wherein a structure including the first reflector and the cladding layer are bonded together, and
the structure including the first reflector and the semiconductor structure are formed from different material systems.

(16) The surface-emitting laser according to any one of (2) to (15),
wherein the current confinement region includes a plurality of the light-emitting region setting parts.

(17) The surface-emitting laser according to any one of (1) to (16), further including:
a cladding layer disposed between the first reflector and the active layer,
wherein the active layer, the semiconductor structure, and the cladding layer are constituted by materials lattice-matched to GaAs.

(18) The surface-emitting laser according to any one of (1) to (17),
wherein a vertical cross-section of the annular step part has a tapered shape. (19) A light source device including:
the surface-emitting laser according to any one of (1) to (18); and
a circuit board bonded to a surface of the surface-emitting laser on the first reflector side thereof.
(20) A ranging device including:
the light source device according to (19); and
a light-receiving element mounted on the circuit board of the light source device.

### REFERENCE SIGNS LIST

1 Ranging device
5 Light source device
10-1 to 10-12, 10-1-1, 10-4-1, 10-5-1, 10-12-1, 20-1 to 20-4 Surface-emitting laser
101 Substrate
102 First reflector
103 Cladding layer (other cladding layer)
104 Active layer
104a Light-emitting region
104a1 Center of light-emitting region
105 Cladding layer (other cladding layer)
106 Tunnel junction layer
107 Cladding layer
107a1, 107b1, 107AB, 107Aa1, 107Ba1 Annular step part
108 Second reflector
IIA Ion implantation region (current confinement region)
IIAa Inner peripheral edge of light-emitting region setting part
SS Semiconductor structure

1. A surface-emitting laser comprising:
first and second reflectors;
an active layer disposed between the first and second reflectors; and
a semiconductor structure disposed between the active layer and the second reflector,
wherein an annular step part is provided on a surface of the semiconductor structure on a side where the second reflector is located.

2. The surface-emitting laser according to claim 1,
wherein the semiconductor structure is provided with a current confinement region having at least one annular light-emitting region setting part that sets a light-emitting region of the active layer, and
in plan view, the annular step part surrounds a center of the light-emitting region.

3. The surface-emitting laser according to claim 2,
wherein in plan view, the annular step part extends along an inner peripheral edge of the light-emitting region setting part.

4. The surface-emitting laser according to claim 3,
wherein in plan view, the annular step part extends along an inner side of the inner peripheral edge.

5. The surface-emitting laser according to claim 3,
wherein in plan view, the annular step part extends along the inner peripheral edge while overlapping with the inner peripheral edge.

6. The surface-emitting laser according to claim 1,
wherein the semiconductor structure includes a cladding layer, one surface of which is the surface.

7. The surface-emitting laser according to claim 6,
wherein a base surface of the annular step part is located within the cladding layer.

8. The surface-emitting laser according to claim 6,
wherein a surface layer including the one surface of the cladding layer is constituted by a material lattice-matched to InP and/or InP.

9. The surface-emitting laser according to claim 8,
wherein the material is a mixed crystal.

10. The surface-emitting laser according to claim 6,
wherein an annular low refractive index layer having a lower refractive index than the cladding layer is provided in contact with the annular step part.

11. The surface-emitting laser according to claim 10,
wherein the low refractive index layer is constituted by a dielectric.

12. The surface-emitting laser according to claim 10,
wherein the second reflector is a dielectric multilayer reflector, and
the low refractive index layer is one of a pair in the dielectric multilayer reflector.

13. The surface-emitting laser according to claim 10,
wherein the low refractive index layer is constituted by SiO₂ or Al₂O₃.

14. The surface-emitting laser according to claim 1,
wherein a vertical cross-section of the annular step part has a tapered shape.

15. The surface-emitting laser according to claim 6,
wherein the semiconductor structure includes:
another cladding layer disposed between the cladding layer and the active layer; and
a tunnel junction layer disposed between the cladding layer and the other cladding layer.

16. The surface-emitting laser according to claim 1, further comprising:
a cladding layer that is disposed between the first reflector and the active layer and is formed from a material system of the same type as the semiconductor structure,
wherein a structure including the first reflector and the cladding layer are bonded together, and
the structure including the first reflector and the semiconductor structure are formed from different material systems.

17. The surface-emitting laser according to claim 1, further comprising:
a cladding layer disposed between the first reflector and the active layer,
wherein the active layer, the semiconductor structure, and the cladding layer are constituted by materials lattice-matched to GaAs.

18. The surface-emitting laser according to claim 2,
wherein the current confinement region includes a plurality of the light-emitting region setting parts.

19. A light source device comprising:
the surface-emitting laser according to claim 1; and
a circuit board bonded to a surface of the surface-emitting laser on the first reflector side thereof.

20. A ranging device comprising:
the light source device according to claim 19; and
a light-receiving element mounted on the circuit board of the light source device.
